(19) United States
(12) Patent Application Publication
(10) Pub. No.: US 2026/0223469 A1
(43) Pub. Date: Jul. 30, 2026

(54) LIGHT DETECTION DEVICE

(71) Applicant: SONY SEMICONDUCTOR SOLUTIONS CORPORATION, KANAGAWA (JP)

(72) Inventor: Atsushi OKUYAMA, KANAGAWA (JP)

(21) Appl. No.: 19/146,938

(22) PCT Filed: Jan. 4, 2024
(86) PCT No.: PCT/JP2024/000025

§ 371 Date: Jul. 10, 2025

(30) Foreign Application Priority Data
Jan. 18, 2023 (JP) 2023-006129

(51) Int. Cl. H10F 39/00; H04N 25/13; H04N 25/772

(52) U.S. Cl. CPC H10F 39/8057; H04N 25/134; H04N 25/772; H10F 39/811

(57) ABSTRACT

Provided is a light detection device capable of improving the optical characteristics. A light detection device includes: a semiconductor substrate having a first surface and a second surface positioned on a side opposite to the first surface, the semiconductor substrate having a plurality of unit pixels arranged in a matrix pattern and, for each of the unit pixels, a plurality of photoelectric conversion units configured to generate charges corresponding to a light receiving amount through photoelectric conversion; an inter-pixel separation unit provided between the adjacent unit pixels, the inter-pixel separation unit having a gap configured to electrically and optically separate the adjacent unit pixels; an intra-pixel separation unit provided between the adjacent photoelectric conversion units within the unit pixels, the intra-pixel separation unit having a first material layer configured to electrically separate the adjacent photoelectric conversion units; and a connection unit provided between the adjacent unit pixels, the connection unit configured to connect the intra-pixel separation unit of one adjacent unit pixel and the intra-pixel separation unit of the other adjacent unit pixel.

### TECHNICAL FIELD

The present disclosure relates to a light detection device.

### BACKGROUND ART

For example, in PTL 1, in an image sensor where one on-chip lens is arranged across a plurality of pixels, trenches are provided between adjacent pixels as well as at the centers of phase difference acquisition pixels.

### CITATION LIST

### Patent Literature

[PTL 1]
U.S. Patent Application Publication No. 2017/0012066 Specification

### SUMMARY

### Technical Problem

In imaging devices where one on-chip lens is arranged across a plurality of pixels as described above, an improvement in optical characteristics is required.

It is an object of the present disclosure to provide a light detection device capable of improving optical characteristics.

### Solution to Problem

A light detection device according to an aspect of the present disclosure includes: a semiconductor substrate having a first surface and a second surface positioned on a side opposite to the first surface, the semiconductor substrate having a plurality of unit pixels arranged in a matrix pattern and, for each of the unit pixels, a plurality of photoelectric conversion units configured to generate charges corresponding to a light receiving amount through photoelectric conversion; an inter-pixel separation unit provided between the adjacent unit pixels, the inter-pixel separation unit having a gap configured to electrically and optically separate the adjacent unit pixels; an intra-pixel separation unit provided between the adjacent photoelectric conversion units within the unit pixels, the intra-pixel separation unit having a first material layer configured to electrically separate the adjacent photoelectric conversion units; and a connection unit provided between the adjacent unit pixels, the connection unit configured to connect the intra-pixel separation unit of one adjacent unit pixel and the intra-pixel separation unit of the other adjacent unit pixel.

According to this configuration, the gap of the inter-pixel separation unit is capable of totally reflecting light incident on the unit pixel and confining the light within the unit pixel. As a result, color mixing between the adjacent unit pixels can be suppressed. Furthermore, as the first material layer of the intra-pixel separation unit, a material with a refractive index close to that of a material (for example, silicon) constituting the semiconductor substrate can be used. As a result, within the unit pixel, the reflection and scattering of light between the adjacent photoelectric conversion units can be suppressed. For the reasons described above, the light detection device is capable of improving the optical characteristics.

### BRIEF DESCRIPTION OF DRAWINGS

FIG. 1 is a diagram showing an example of the overall configuration of an imaging device according to embodiments of the present disclosure.

FIG. 2 illustrates an example of the reading-out circuit of a unit pixel of the imaging device shown in FIG. 1.

FIG. 3 is a plan view showing a configuration example of the imaging device according to a first embodiment of the present disclosure.

FIG. 4 is a simplified view of the plan view shown in FIG. 3, and is a plan view showing the positional relationship between an inter-pixel separation unit, an intra-pixel separation unit, a connection unit, and a color filter.

FIG. 5 is a cross-sectional view obtained by cutting the plan view shown in FIG. 4 along the line A-A′.

FIG. 6 is a cross-sectional view obtained by cutting the plan view shown in FIG. 4 along the line B-B′.

FIG. 7 is a cross-sectional view obtained by cutting the plan view shown in FIG. 4 along the line C-C′.

FIG. 8 is a plan view showing an imaging device according to a first modified example of the first embodiment of the present disclosure.

FIG. 9 is a plan view showing an imaging device according to a second modified example of the first embodiment of the present disclosure.

FIG. 10 is a plan view showing an imaging device according to a third modified example of the first embodiment of the present disclosure.

FIG. 11 is a cross-sectional view showing a configuration example of an imaging device according to a second embodiment of the present disclosure.

FIG. 12 is a plan view showing a configuration example of an imaging device according to a third embodiment of the present disclosure.

FIG. 13 is a cross-sectional view showing a configuration example of the imaging device according to the third embodiment of the present disclosure.

FIG. 14 is a cross-sectional view showing a configuration example of the imaging device according to the third embodiment of the present disclosure.

FIG. 15 is a cross-sectional view showing a configuration example of the imaging device according to the third embodiment of the present disclosure.

FIG. 16A is a view showing a manufacturing method for the imaging device according to a fourth embodiment of the present disclosure, in the order of steps.

FIG. 16B is a view showing a manufacturing method for the imaging device according to a fourth embodiment of the present disclosure, in the order of steps.

FIG. 16C is a view showing a manufacturing method for the imaging device according to a fourth embodiment of the present disclosure, in the order of steps.

FIG. 16D is a view showing a manufacturing method for the imaging device according to a fourth embodiment of the present disclosure, in the order of steps.

FIG. 17 is a view showing the manufacturing method for the imaging device according to a first modified example of the fourth embodiment of the present disclosure, in the order of steps.

FIG. 18A is a view showing the manufacturing method for the imaging device according to a second modified example of the fourth embodiment of the present disclosure, in the order of steps.

FIG. 18B is a view showing the manufacturing method for the imaging device according to a second modified example of the fourth embodiment of the present disclosure, in the order of steps.

FIG. 18C is a view showing the manufacturing method for the imaging device according to a second modified example of the fourth embodiment of the present disclosure, in the order of steps.

FIG. 19A is a view showing a manufacturing method for the imaging device according to a fifth embodiment of the present disclosure, in the order of steps.

FIG. 19B is a view showing a manufacturing method for the imaging device according to a fifth embodiment of the present disclosure, in the order of steps.

FIG. 20A is a view showing a manufacturing method for the imaging device according to a sixth embodiment of the present disclosure, in the order of steps.

FIG. 20B is a view showing a manufacturing method for the imaging device according to a sixth embodiment of the present disclosure, in the order of steps.

FIG. 20C is a view showing a manufacturing method for the imaging device according to a sixth embodiment of the present disclosure, in the order of steps.

FIG. 20D is a view showing a manufacturing method for the imaging device according to a sixth embodiment of the present disclosure, in the order of steps.

FIG. 21 is a diagram showing a schematic configuration of electronic equipment.

FIG. 22 is a block diagram showing a schematic configuration example of a vehicle control system, which is an example of a moving body control system to which the technology according to the present disclosure can be applied.

FIG. 23 is a diagram showing an example of the installation position of an imaging unit.

FIG. 24 is a diagram showing an example of the schematic configuration of an endoscopic surgery system to which the technology according to the present disclosure (the present technology) can be applied.

FIG. 25 is a block diagram showing examples of the functional configurations of a camera head and a CCU shown in FIG. 24.

### DESCRIPTION OF EMBODIMENTS

Embodiments of the present disclosure will be described below with reference to the drawings. In the drawings referred to in the following descriptions, the same or similar portions are denoted by same or similar reference numerals. However, it should be noted that the drawings are schematic, and the relationships between thicknesses and planar dimensions, the ratios of the thicknesses of respective layers, and the like differ from actual ones. Accordingly, specific thicknesses and dimensions should be determined in light of the following descriptions. Furthermore, it goes without saying that the drawings include portions where the relationships and ratios of dimensions differ from each other.

Furthermore, it should be understood that the definitions of directions such as up and down in the following descriptions are merely for the sake of convenience and are not intended to limit the technical spirit of the present disclosure. For example, it goes without saying that when an object is observed after being rotated by 90°, up and down are converted into left and right, and when the object is observed after being rotated by 180°, up and down are inverted.

Furthermore, in the following descriptions, the directions may be described using the terms X-axis direction, Y-axis direction, and Z-axis direction. For example, the Z-axis direction represents the thickness direction of a semiconductor substrate 11, which will be described later. The X-axis direction and the Y-axis direction represent the directions orthogonal to the Z-axis direction. The X-axis direction, the Y-axis direction, and the Z-axis direction are orthogonal to each other.

### First Embodiment

### (Example of Overall Configuration of Imaging Device)

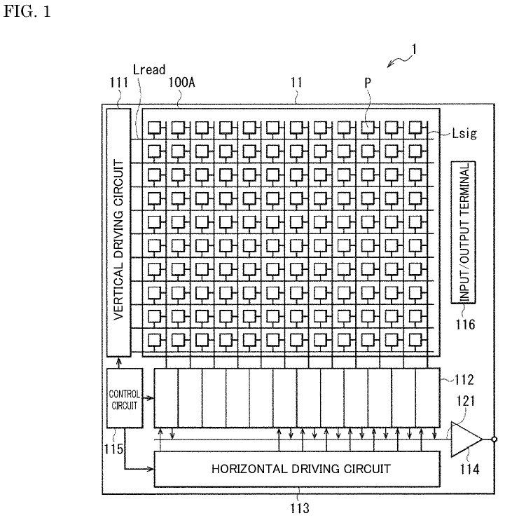

FIG. 1 is a diagram showing an example of the overall configuration of an imaging device 1 according to an embodiment of the present disclosure. The imaging device 1 is an example of a “light detection device” in the present disclosure and is, for example, a CMOS (Complementary Metal Oxide Semiconductor) image sensor or the like, which is used in electronic equipment such as digital still cameras or video cameras. The imaging area of the imaging device 1 includes a pixel unit (pixel unit 100A) where a plurality of pixels are two-dimensionally arranged in a matrix pattern. The imaging device 1 is, for example, a back-illuminated imaging device in this CMOS image sensor or the like.

The imaging device 1 takes in incident light (image light) from a subject through an optical lens system (not shown), converts the amount of the incident light formed on the imaging surface into electrical signals for each pixel, and outputs the signals as pixel signals. The imaging device 1 has the pixel unit 100A as the imaging area on the semiconductor substrate 11 and has, for example, a vertical driving circuit 111, a column signal processing circuit 112, a horizontal driving circuit 113, an output circuit 114, a control circuit 115, and an input/output terminal 116 in the peripheral region of the pixel unit 100A.

In the pixel unit 100A, a plurality of unit pixels P are, for example, two-dimensionally arranged in a matrix pattern. Each of the plurality of unit pixels P functions as both an imaging pixel and an image surface phase-difference pixel. The imaging pixel photoelectrically converts a subject image formed by an imaging lens in a photodiode (PD) to generate a signal for image generation. The image surface phase-difference pixel divides the pupil region of the imaging lens and photoelectrically converts the subject image from the divided pupil region to generate a signal for phase-difference detection.

For the unit pixels P, for example, a pixel driving line Lread (specifically, a row selection line and a reset control line) is wired for each pixel row, and a vertical signal line Lsig is wired for each pixel column. The pixel driving line Lread transmits a driving signal for reading out the signal from the pixel. One end of the pixel driving line Lread is connected to an output terminal of the vertical driving circuit 111 that corresponds to each row.

The vertical driving circuit 111 is a pixel driving unit that is composed of a shift register, an address decoder, and the like and drives each unit pixel P of the pixel unit 100A, for example, on a row-by-row basis. The signal output from each unit pixel P in a pixel row selectively scanned by the vertical driving circuit 111 is supplied to the column signal processing circuit 112 via each vertical signal line Lsig. The column signal processing circuit 112 is composed of an amplifier, a horizontal selection switch, and the like provided for each vertical signal line Lsig.

The horizontal driving circuit 113 is composed of a shift register, an address decoder, and the like and sequentially drives each horizontal selection switch of the column signal processing circuit 112 while performing scanning. By the selective scanning of the horizontal driving circuit 113, the signal of each pixel transmitted via each vertical signal line Lsig is sequentially output to a horizontal signal line 121 and transmitted to the outside of the semiconductor substrate 11 via the horizontal signal line 121.

The output circuit 114 performs signal processing on the signals sequentially supplied via the horizontal signal line 121 from each column signal processing circuit 112 and outputs the processed signals. For example, the output circuit 114 may perform only buffering, or it may perform black level adjustment, column variation compensation, various digital signal processing, and the like.

The circuit portions of the vertical driving circuit 111, the column signal processing circuit 112, the horizontal driving circuit 113, the horizontal signal line 121, and the output circuit 114 may be directly formed on the semiconductor substrate 11, or they may be arranged in an external control IC. Furthermore, these circuit portions may also be formed on other substrates connected by cables or the like.

The control circuit 115 receives the clocks supplied from outside of the semiconductor substrate 11, data instructing an operation mode, and the like and outputs data such as the internal information of the imaging device 1. The control circuit 115 also has a timing generator that generates various timing signals. On the basis of the generated various timing signals, the control circuit 115 controls the driving of peripheral circuits including the vertical driving circuit 111, the column signal processing circuit 112, the horizontal driving circuit 113, and the like.

The input/output terminal 116 exchanges signals with the outside.

### (Circuit Configuration Example of Unit Pixel)

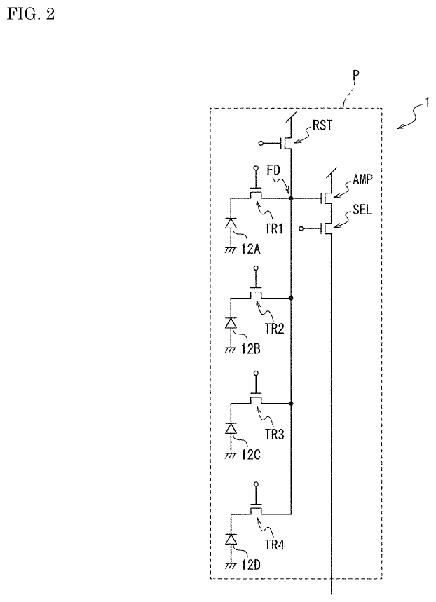

FIG. 2 illustrates an example of the reading-out circuit of the unit pixel P of the imaging device 1 shown in FIG. 1. As shown in FIG. 2, the unit pixel P has, for example, four photoelectric conversion units 12A, 12B, 12C, and 12D, transfer transistors TR1, TR2, TR3, and TR4, a floating diffusion FD, a reset transistor RST, an amplification transistor AMP, and a selection transistor SEL.

Each of the photoelectric conversion units 12A, 12B, 12C, and 12D is, for example, a photodiode (PD). The photoelectric conversion unit 12A has its anode connected to a grounded voltage line and its cathode connected to the source of the transfer transistor TR1. Like the photoelectric conversion unit 12A, the photoelectric conversion units 12B, 12C, and 12D have their anodes connected to grounded voltage lines and their cathodes connected to the sources of the transfer transistors TR2, TR3, and TR4, respectively.

The transfer transistor TR1 is connected between the photoelectric conversion unit 12A and the floating diffusion FD. The transfer transistor TR2 is connected between the photoelectric conversion unit 12B and the floating diffusion FD. The transfer transistor TR3 is connected between the photoelectric conversion unit 12C and the floating diffusion FD. The transfer transistor TR4 is connected between the photoelectric conversion unit 12D and the floating diffusion FD.

A driving signal TRsig is applied to each gate electrode of the transfer transistors TR1, TR2, TR3, and TR4. When this driving signal TRsig becomes active, the respective transfer gates of the transfer transistors TR1, TR2, TR3, and TR4 become conductive, thereby causing the signal charges accumulated in each of the photoelectric conversion units 12A, 12B, 12C, and 12D to be transferred to the floating diffusion FD via the transfer transistors TR1, TR2, TR3, and TR4.

The floating diffusion FD is connected between the transfer transistors TR1, TR2, TR3, and TR4 and the amplification transistor AMP. The floating diffusion FD converts the signal charges transferred from the transfer transistors TR1, TR2, TR3, and TR4 into voltage signals and outputs the converted signals to the amplification transistor AMP.

The reset transistor RST is connected between the floating diffusion FD and a power supply unit. A driving signal RSTsig is applied to the gate electrode of the reset transistor RST. When this driving signal RSTsig becomes active, the reset gate of the reset transistor RST becomes conductive, thereby causing the potential of the floating diffusion FD to be reset to the level of the power supply unit.

The amplification transistor AMP has its gate electrode connected to the floating diffusion FD and its drain electrode connected to the power supply unit, serving as a reading-out circuit for the voltage signal retained by the floating diffusion FD, which is the input unit of a so-called source-follower circuit. In other words, the amplification transistor AMP has its source electrode connected to the vertical signal line Lsig via the selection transistor SEL, thereby constituting a source-follower circuit with a constant current source connected to one end of the vertical signal line Lsig.

The selection transistor SEL is connected between the source electrode of the amplification transistor AMP and the vertical signal line Lsig. A driving signal SELsig is applied to the gate electrode of the selection transistor SEL. When this driving signal SELsig becomes active, the selection transistor SEL becomes conductive, thereby causing the unit pixel P to be in a selected state. As a result, the reading-out signal (pixel signal) output from the amplification transistor AMP is output to the vertical signal line Lsig via the selection transistor SEL.

In the unit pixel P, for example, signal charges generated in the photoelectric conversion unit 12A, signal charges generated in the photoelectric conversion unit 12B, signal charges generated in the photoelectric conversion unit 12C, and signal charges generated in the photoelectric conversion unit 12D are each read out. By outputting the signal charges read out from each of the photoelectric conversion units 12A, 12B, 12C, and 12D to, for example, the phase difference operation block of an external signal processing unit, a signal for phase difference autofocus can be acquired. Furthermore, by summing the signal charges read out from each of the photoelectric conversion units 12A, 12B, 12C, and 12D in the floating diffusion FD and outputting the summed signal charges to, for example, the imaging block of an external signal processing unit, a pixel signal based on the total charges of the photoelectric conversion units 12A, 12B, 12C, and 12D can be acquired.

### (Configuration Example of Unit Pixel in Cross-Sectional View and Plan View)

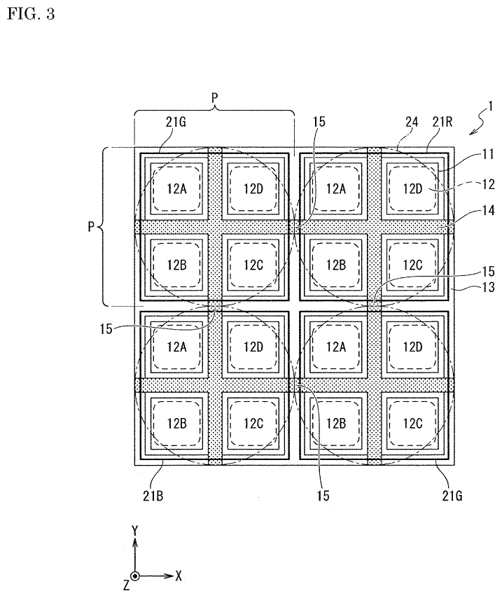

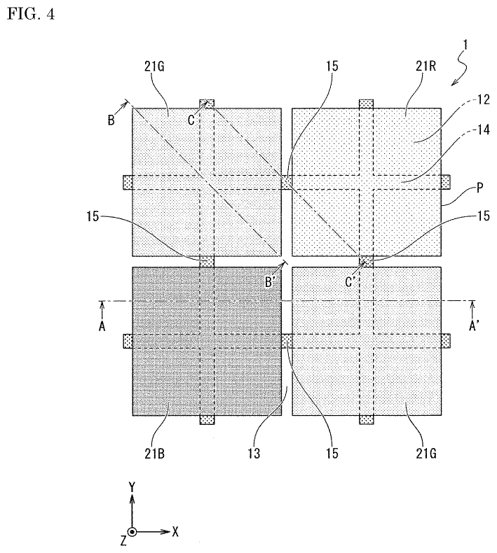

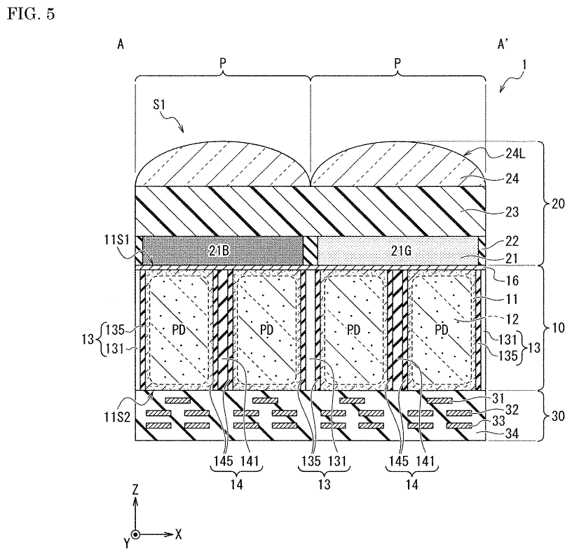

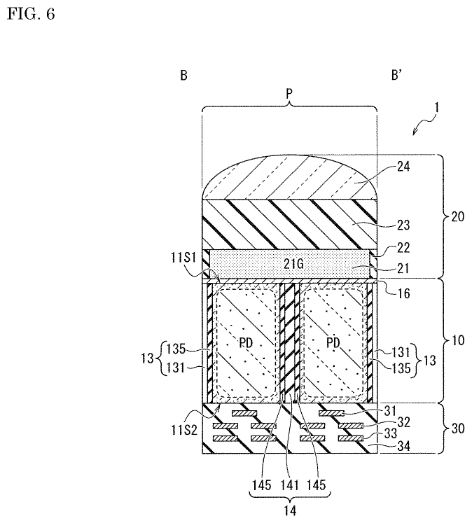

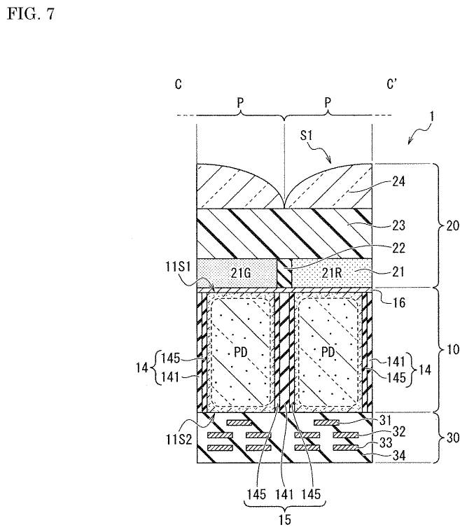

FIG. 3 is a plan view showing a configuration example of the imaging device 1 according to a first embodiment of the present disclosure. FIG. 4 is a simplified view of the plan view shown in FIG. 3, and is a plan view showing the positional relationship between an inter-pixel separation unit 13, an intra-pixel separation unit 14, a connection unit 15, and a color filter 21. In FIG. 4, the illustration of on-chip lenses 24 shown in FIG. 3 is omitted. FIG. 5 is a cross-sectional view obtained by cutting the plan view shown in FIG. 4 along the line A-A′. FIG. 6 is a cross-sectional view obtained by cutting the plan view shown in FIG. 4 along the line B-B′. FIG. 7 is a cross-sectional view obtained by cutting the plan view shown in FIG. 4 along the line C-C′.

The imaging device 1 shown in FIGS. 3 to 7 is, for example, a back-illuminated imaging device as described above. As shown in FIGS. 3 and 4, each of the plurality of unit pixels P, which are two-dimensionally arranged in the pixel unit 100A in a matrix pattern (see FIG. 1), has, for example, a light receiving unit 10, a focusing unit 20 provided on the side of a first surface 11S1, which serves as the light incident surface of the light receiving unit 10, and a multilayer wiring layer 30 provided on the side of a second surface 11S2, which is opposite to the first surface 11S1 of the light receiving unit 10. Note that the first surface 11S1 corresponds to a back surface while the second surface 11S2 corresponds to a front surface because the imaging device 1 is of a back-illuminated type.

As shown in FIGS. 5 to 7, the light receiving unit 10 has a semiconductor substrate 11 with the first surface 11S1 and the second surface 11S2 facing each other, and a plurality of photoelectric conversion units 12 embedded in the semiconductor substrate 11. The semiconductor substrate 11 is made of, for example, a silicon substrate. The photoelectric conversion units 12 are, for example, PIN (Positive Intrinsic Negative) photodiodes (PD) and have a pn-junction in the specified region of the semiconductor substrate 11. As described above, the plurality of photoelectric conversion units 12 are embedded in the unit pixel P. For example, the four photoelectric conversion units 12A, 12B, 12C, and 12D are embedded in the unit pixel P.

The light receiving unit 10 also has the inter-pixel separation unit 13, the intra-pixel separation unit 14, and the connection unit 15. The inter-pixel separation unit 13 is provided between the adjacent unit pixels P. In other words, the inter-pixel separation unit 13 is provided around the unit pixel P. In the pixel unit 100A, the inter-pixel separation units 13 are provided in a lattice pattern in a plan view as shown in, for example, FIGS. 3 and 4. The inter-pixel separation unit 13 electrically and optically separates the adjacent unit pixels P. The inter-pixel separation unit 13 penetrates between the first surface 11S1 and the second surface 11S2 of the semiconductor substrate 11 along, for example, the thickness direction (for example, the Z-axis direction) of the semiconductor substrate 11.

As shown in FIGS. 5 and 6, the inter-pixel separation unit 13 has a gap 131 and an insulating film 135 (an example of a “first insulating film” in the present disclosure) provided between the gap 131 and the semiconductor substrate 11. The gap 131 is a slit that penetrates between the first surface 11S1 and the second surface 11S2 of the semiconductor substrate 11. The insulating film 135 is provided around this slit (i.e., the gap 131). As shown in FIG. 4, these slits (i.e., the gaps 131) are provided in a lattice pattern in a plan view. Note that the gap 131 may be referred to as an air layer.

The insulating film 135 is, for example, a silicon oxide (SiOx) film, an aluminum oxide (AlOx) film, or a hafnium oxide (HfOx) film. For example, by using a silicon oxide (SiOx) film, an aluminum oxide (AlOx) film, or a hafnium oxide (HfOx) film as the insulating film 135, the insulating film 135 can serve as a pinning film with a negative fixed charge. The electric field induced by this pinning film can form a hole accumulation layer in the semiconductor substrate 11 that is in contact with the pinning film and can suppress the generation of dark current due to the interface level of the semiconductor substrate 11 that is in contact with the pinning film.

Note that, as shown in FIGS. 3 and 4, the inter-pixel separation unit 13 when seen in a plan view is positioned between the unit pixel P that overlaps with the red color filter 21R in a plan view and the unit pixel P that overlaps with the green color filter 21G in a plan view, as well as between the unit pixel P that overlaps with the blue color filter 21B in a plan view and the unit pixel P that overlaps with the green color filter 21G in a plan view. The inter-pixel separation unit 13 separates different colors in a plan view. For this reason, the inter-pixel separation unit 13 may be referred to as a “different-color separation unit.”

As shown in FIG. 3, the intra-pixel separation unit 14 is provided between the adjacent photoelectric conversion units 12A, 12B, 12C, and 12D in the unit pixel P. The intra-pixel separation unit 14 electrically separates the adjacent photoelectric conversion units 12A, 12B, 12C, and 12D. As shown in FIGS. 3 and 4, the intra-pixel separation units 14 are provided in a lattice pattern in a plan view.

As shown in FIGS. 5 to 7, the intra-pixel separation unit 14 penetrates between the first surface 11S1 and the second surface 11S2 of the semiconductor substrate 11 along the thickness direction (for example, the Z-axis direction) of the semiconductor substrate 11 like the inter-pixel separation unit 13.

The intra-pixel separation unit 14 has a first material layer 141 and an insulating film 145 (an example of a “second insulating film” in the present disclosure) provided between the first material layer 141 and the semiconductor substrate 11. The first material layer 141 penetrates between the first surface 11S1 and the second surface 11S2 of the semiconductor substrate 11. The insulating film 145 is provided around the first material layer 141.

The first material layer 141 is preferably made of a material with a refractive index close to that of the semiconductor substrate 11 and is preferably made of, for example, a material with a refractive index of 0.6 times or more and 1.4 times or less of the refractive index of the semiconductor substrate 11. Because the semiconductor substrate 11 is silicon (Si), the first material layer 141 is preferably made of a material with a refractive index close to that of silicon and is preferably made of a material with a refractive index of 0.6 times or more and 1.4 times or less of the refractive index of silicon. As the first material layer 141 that satisfies such conditions, titanium oxide (TiOx; for example, TiO₂), iron oxide (FexOy; for example, Fe₂O₃), or a laminated film of titanium oxide and iron oxide is exemplified.

The configuration where the first material layer 141 is made of a material (for example, TiO₂, Fe₂O₃) with a refractive index close to that of the semiconductor substrate 11 can suppress the reflection of light between the first material layer 141 and the semiconductor substrate 11, enabling an improvement in the optical characteristics of the unit pixel P.

Note that the first material layer 141 is not limited to TiOx or FexOy, but it may also be, for example, SiOx (for example, SiO₂), SiNx (for example, Si₃N₄), or a laminated film of SiOx and SiNx. Alternatively, the first material layer 141 may also be one or more of tantalum oxide (TaOx), diamond, zirconium oxide (ZrOx), hafnium oxide (HfOx), cerium oxide (CeOx), aluminum oxide (AlOx), or niobium oxide (NbOx). The first material layer 141 may also be non-doped polysilicon (Poly-Si) or amorphous silicon (a-Si).

The insulating film 145 is, for example, a silicon oxide (SiOx) film, an aluminum oxide (AlOx) film, or a hafnium oxide (HfOx) film. For example, by using a silicon oxide (SiOx) film, an aluminum oxide (AlOx) film, or a hafnium oxide (HfOx) film as the insulating film 145, the insulating film 145 can serve as a pinning film with a negative fixed charge. The electric field induced by this pinning film can form a hole accumulation layer in the semiconductor substrate 11 that is in contact with the pinning film and can suppress the generation of dark current due to the interface level of the semiconductor substrate 11 that is in contact with the pinning film.

Note that, as shown in FIGS. 3 and 4, the intra-pixel separation units 14 are positioned between the photoelectric conversion units 12A, 12B, 12C, and 12D that overlap with the color filters 21 of the same color in a plan view. The intra-pixel separation unit 14 separates the regions of the same color in a plan view. For this reason, the intra-pixel separation unit 14 may be referred to as a “same-color separation unit.”

As shown in FIGS. 3 and 4, the connection units 15 are provided between the adjacent unit pixels P to connect the intra-pixel separation unit 14 of one adjacent unit pixel P and the intra-pixel separation unit 14 of the other adjacent unit pixel P. The connection unit 15 is integrally formed with the intra-pixel separation unit 14. As shown in FIG. 7, the connection unit 15 has, for example, the first material layer 141 and the insulating film 145. The first material layer 141 included in the connection unit 15 has the same composition as that of the first material layer 141 included in the intra-pixel separation unit 14. The first material layer 141 included in the connection unit 15 is integrally formed with the first material layer 141 included in the intra-pixel separation unit 14. Similarly, the insulating film 145 of the connection unit 15 has the same composition as that of the insulating film 145 of the intra-pixel separation unit 14. The insulating film 145 included in the connection unit 15 is integrally formed with the insulating film 145 included in the intra-pixel separation unit 14.

As shown in FIGS. 5 to 7, a fixed charge layer 16 that also serves to prevent reflection at the first surface 11S1 of the semiconductor substrate 11 is provided on the first surface 11S1 of the semiconductor substrate 11. The fixed charge layer 16 may be a film with positive fixed charges or a film with negative fixed charges. Examples of the constituent materials of the fixed charge layer 16 include a semiconductor material or a conductive material with a band gap wider than that of the semiconductor substrate 11. Specific examples of the constituent materials include hafnium oxide (HfOx), aluminum oxide (AlOx), zirconium oxide (ZrOx), tantalum oxide (TaOx), titanium oxide (TiOx), lanthanum oxide (LaOx), praseodymium oxide (PrOx), cerium oxide (CeOx), neodymium oxide (NdOx), promethium oxide (PmOx), samarium oxide (SmOx), europium oxide (EuOx), gadolinium oxide (GdOx), terbium oxide (TbOx), dysprosium oxide (DyOx), holmium oxide (HoOx), thulium oxide (TmOx), ytterbium oxide (YbOx), lutetium oxide (LuOx), yttrium oxide (YOx), hafnium nitride (HfNx), aluminum nitride (AlNx), hafnium oxynitride (HfOxNy), and aluminum oxynitride (AlOxNy), and the like. The fixed charge layer 16 may be a single layer film or a laminated film made of different materials.

The focusing unit 20 is provided on the first surface 11S1 of the light receiving unit 10 and includes, for example, a color filter 21 that selectively transmits a color preset for each unit pixel P, such as red light (R), green light (G), or blue light (B), a light shielding unit 22 that is provided between the unit pixels P of the color filters 21, a flattening layer 23, and a lens layer 24L, which are stacked in this order from the side of the light receiving unit 10.

As shown in FIG. 3, for example, in the color filter 21, with respect to four unit pixels P arranged in two rows and two columns, two color filters 21G that selectively transmit green light (G) are arranged along one diagonal, and color filters 21R and 21B that selectively transmit red light (R) and blue light (B) are arranged one by one along the orthogonal diagonal. In the unit pixels P where the color filters 21R, 21G, and 21B are provided, corresponding colored light is detected in, for example, each of the photoelectric conversion units 12. In other words, in the pixel unit 100A, the unit pixels P that detect red light (R), green light (G), and blue light (B) are arranged in a Bayer pattern.

The light shielding unit 22 prevents light incident obliquely on the color filter 21 from leaking into the adjacent unit pixels P and is provided between the unit pixels P of the color filters 21 as described above. In other words, the light shielding units 22 are arranged in a lattice pattern in the pixel unit 100A. Examples of the constituent materials of the light shielding unit 22 include conductive materials with light shielding properties. Specific examples of the constituting materials include tungsten (W), silver (Ag), copper (Cu), aluminum (Al), alloys of Al and copper (Cu), and the like.

The flattening layer 23 flattens the surface on a light incidence side S1, which is composed of the color filters 21 and the light shielding units 22. The flattening layer 23 is made of, for example, silicon oxide (SiOx), silicon nitride (SiNx), silicon oxynitride (SiOxNy), and the like.

The lens layer 24L is provided to cover the entire surface of the pixel unit 100A and has, for example, a plurality of gapless on-chip lenses 24 on its surface. The on-chip lenses 24 focus light incident from above onto the photoelectric conversion units 12 and are provided, for example, for each unit pixel P. In other words, the on-chip lenses 24 are provided across the plurality of photoelectric conversion units 12 within the unit pixels P. Furthermore, in a plan view, the inter-pixel separation units 13 and the boundaries between the plurality of on-chip lenses 24 are substantially aligned.

The lens layer 24L is made of, for example, an inorganic material such as silicon oxide (SiOx) or silicon nitride (SiNx). In addition, the lens layer 24L may also be made of an organic material with a high refractive index, such as episulfide resin, thiethane compounds, or resins thereof. The shape of the on-chip lenses 24 is not particularly limited, and various lens shapes, such as a semi-spherical shape or a semi-cylindrical shape, can be adopted.

The multilayer wiring layer 30 is provided on the side opposite to the first surface 11S1 of the light receiving unit 10, specifically, on the side of the second surface 11S2 of the semiconductor substrate 11. The multilayer wiring layer 30 has, for example, a configuration where a plurality of wiring layers 31, 32, and 33 are stacked with an interlayer insulating layer 34 interposed therebetween. In the multilayer wiring layer 30, for example, the vertical driving circuit 111, the column signal processing circuit 112, the horizontal driving circuit 113, the output circuit 114, the control circuit 115, the input/output terminal 116, and the like are formed in addition to the above-described reading-out circuit.

The wiring layers 31, 32, and 33 are made of, for example, aluminum (Al), copper (Cu), tungsten (W), or the like. In addition, the wiring layers 31, 32, and 33 may also be made of polysilicon (Poly-Si).

The interlayer insulating layer 34 is formed by, for example, a single-layer film made of one of silicon oxide (SiOx), TEOS, silicon nitride (SiNx), silicon oxynitride (SiOxNy), or the like, or by a stacked film made of two or more of these materials.

### Effects of First Embodiment

As described above, the imaging device 1 according to the first embodiment of the present disclosure includes: the semiconductor substrate 11 having the first surface 11S1 and the second surface 11S2 positioned on the side opposite to the first surface 11S1, the semiconductor substrate having the plurality of unit pixels P arranged in a matrix pattern and, for each of the unit pixels P, the plurality of photoelectric conversion units 12 that generate charges corresponding to a light receiving amount through photoelectric conversion; the inter-pixel separation unit 13 provided between the adjacent unit pixels P, the inter-pixel separation unit 13 having the gap 131 that electrically and optically separates the adjacent unit pixels P; the intra-pixel separation unit 14 provided between the adjacent photoelectric conversion units 12A, 12B, 12C, and 12D within the unit pixels P, the intra-pixel separation unit 14 having the first material layer 141 that electrically separates the adjacent photoelectric conversion units 12; and the connection unit 15 provided between the adjacent unit pixels P, the connection unit 15 connecting the intra-pixel separation unit 14 of one adjacent unit pixel P and the intra-pixel separation unit 14 of the other adjacent unit pixel P.

According to this configuration, the gap 131 of the inter-pixel separation unit 13 is capable of totally reflecting light incident on the unit pixel P and confining the light within the unit pixel P. As a result, color mixing between the adjacent unit pixels P can be suppressed. Furthermore, as the first material layer 141 of the intra-pixel separation unit 14, a material with a refractive index close to that of a material (for example, silicon) constituting the semiconductor substrate 11 can be used. As a result, within the unit pixel P, the reflection and scattering of light between the adjacent photoelectric conversion units 12A, 12B, 12C, and 12D can be suppressed. For the reasons described above, the imaging device 1 is capable of improving the optical characteristics.

Furthermore, as the miniaturization and high integration of the unit pixels P progress, the aspect ratio of the gap 131 in the inter-pixel separation unit 13 is expected to increase. If the aspect ratio of the gap 131 increases, a pattern including the intra-pixel separation unit 14 is likely to collapse in, for example, a washing or etching process using a liquid, or in a drying process after washing or etching. However, in the imaging device 1, the intra-pixel separation unit 14 of one adjacent unit pixel P and the intra-pixel separation unit 14 of the other adjacent unit pixel P are connected by the connection unit 15 arranged between the unit pixels P. As a result, the collapse of the pattern can be suppressed.

### Modified Example of First Embodiment

In the above first embodiment, one unit pixel P has four photoelectric conversion units 12A, 12B, 12C, and 12D as shown in FIG. 3. The unit pixel P shown in FIG. 4 is also referred to as a 2×2 type in this specification because the four photoelectric conversion units 12A, 12B, 12C, and 12D are arranged two by two in both the X-axis direction and the Y-axis direction. However, in the embodiments of the present disclosure, the configuration of the unit pixel P is not limited to the 2×2 type.

### (1) First Modified Example

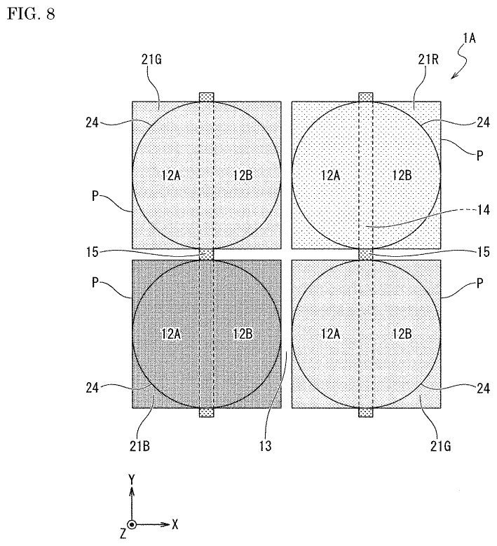

FIG. 8 is a plan view showing an imaging device 1A according to a first modified example of the first embodiment of the present disclosure. The imaging device 1A shown in FIG. 8 is an example of the “light detection device” of the present disclosure. In the imaging device 1A, each of the plurality of unit pixels P has two photoelectric conversion units 12A and 12B. The unit pixel P shown in FIG. 8 is also referred to as a 2×1 type in the present specification because the two photoelectric conversion units 12A and 12B are arranged in the X-axis direction but not in the Y-axis direction.

The imaging device 1A including the unit pixels P of the 2×1 type shown in FIG. 8 includes: the inter-pixel separation unit 13 provided between the adjacent unit pixels P, the inter-pixel separation unit 13 having the gap 131 that electrically and optically separates the adjacent unit pixels P; the intra-pixel separation unit 14 provided between the adjacent photoelectric conversion units 12A and 12B within the unit pixels P, the intra-pixel separation unit 14 having the first material layer 141 that electrically separates the adjacent photoelectric conversion units 12; and the connection unit 15 provided between the adjacent unit pixels P, the connection unit 15 connecting the intra-pixel separation unit 14 of one adjacent unit pixel P and the intra-pixel separation unit 14 of the other adjacent unit pixel P.

As a result, like the imaging device 1, the imaging device 1A can prevent color mixing between the adjacent unit pixels P and suppress the reflection and scattering of light between the adjacent photoelectric conversion units 12A and 12B within the unit pixels P. Furthermore, in the imaging device, the connection unit 15 connects the intra-pixel separation unit 14 of one adjacent unit pixel P and the intra-pixel separation unit 14 of the other adjacent unit pixel P. Therefore, even when the aspect ratio of the gap 131 increases, the collapse of the pattern can be suppressed.

### (2) Second Modified Example

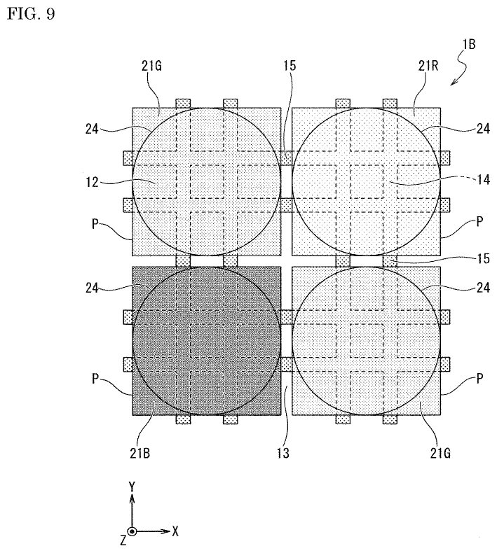

FIG. 9 is a plan view showing an imaging device 1B according to a second modified example of the first embodiment of the present disclosure. The imaging device 1B shown in FIG. 9 is an example of the “light detection device” of the present disclosure. In the imaging device 1B, each of the plurality of unit pixels P has nine photoelectric conversion units 12. The unit pixel P shown in FIG. 9 is also referred to as a 3×3 type in the present specification because the nine photoelectric conversion units 12 are arranged three by three in both the X-axis direction and the Y-axis direction.

The imaging device 1B including the unit pixels P of the 3×3 type shown in FIG. 9 includes the inter-pixel separation unit 13 having the gap 131, the intra-pixel separation unit 14 having the first material layer 141, and the connection unit 15. As a result, like the imaging device 1, the imaging device 1B can prevent color mixing between the adjacent unit pixels P and suppress the reflection and scattering of light between the plurality of adjacent (for example, nine) photoelectric conversion units 12 within the unit pixels P. Furthermore, in the imaging device 1B, the connection unit 15 connects the intra-pixel separation unit 14 of one adjacent unit pixel P and the intra-pixel separation unit 14 of the other adjacent unit pixel P. Therefore, even when the aspect ratio of the gap 131 increases, the collapse of the pattern can be suppressed.

### (3) Third Modified Example

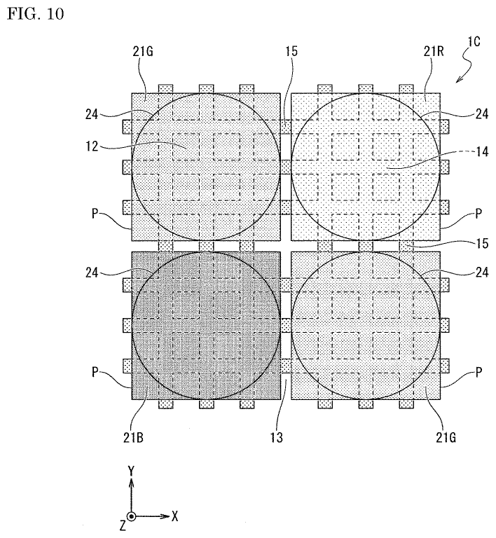

FIG. 10 is a plan view showing an imaging device 1C according to a third modified example of the first embodiment of the present disclosure. The imaging device 1C shown in FIG. 10 is an example of the “light detection device” of the present disclosure. In the imaging device 1C, each of the plurality of unit pixels P has 16 photoelectric conversion units 12. The unit pixel P shown in FIG. 10 is also referred to as a 4×4 type in the present specification because the 16 photoelectric conversion units 12 are arranged four by four in both the X-axis direction and the Y-axis direction.

The imaging device 1C including the unit pixels P of the 4×4 type shown in FIG. 10 includes the inter-pixel separation unit 13 having the gap 131, the intra-pixel separation unit 14 having the first material layer 141, and the connection unit 15. As a result, like the imaging device 1, the imaging device 1C can prevent color mixing between the adjacent unit pixels P and suppress the reflection and scattering of light between the plurality of adjacent (for example, 16) photoelectric conversion units 12 within the unit pixels P. Furthermore, in the imaging device 1C, the connection unit 15 connects the intra-pixel separation unit 14 of one adjacent unit pixel P and the intra-pixel separation unit 14 of the other adjacent unit pixel P. Therefore, even when the aspect ratio of the gap 131 increases, the collapse of the pattern can be suppressed.

### Second Embodiment

In the above first embodiment, as shown in FIGS. 5 to 7, each of the inter-pixel separation unit 13 and the intra-pixel separation unit 14 penetrates between the first surface 11S1 and the second surface 11S2 of the semiconductor substrate 11 along the thickness direction (for example, the Z-axis direction) of the semiconductor substrate 11. However, the embodiments of the present disclosure are not limited to this. At least one of the inter-pixel separation unit 13 and the intra-pixel separation unit 14 may not penetrate the semiconductor substrate 11.

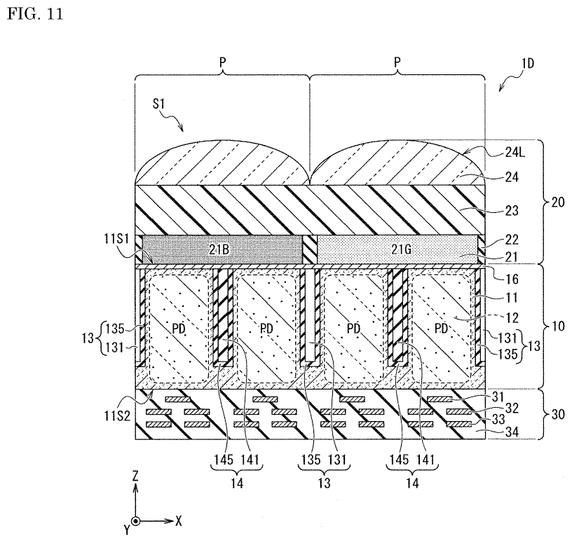

FIG. 11 is a cross-sectional view showing a configuration example of an imaging device 1D according to a second embodiment of the present disclosure. The imaging device 1D shown in FIG. 11 differs from the imaging device 1 shown in FIG. 5 and the like in that the inter-pixel separation unit 13 and the intra-pixel separation unit 14 do not penetrate the semiconductor substrate 11. In the imaging device 1D, the inter-pixel separation unit 13 and the intra-pixel separation unit 14 are provided to extend from the side of the first surface 11S1 of the semiconductor substrate 11 to a halfway position in the thickness direction (for example, the Z-axis direction) of the semiconductor substrate 11. Note that the first surface 11S1 corresponds to a back surface because the imaging device 1D is, for example, of a back-illuminated type.

For example, the inter-pixel separation unit 13 has the gap 131 and the insulating film 135 provided between the gap 131 and the semiconductor substrate 11. The gap 131 and the insulating film 135 are provided to extend from the side of the first surface 11S1, which corresponds to the back surface of the semiconductor substrate 11, to a halfway position in the thickness direction (for example, the Z-axis direction) of the semiconductor substrate 11. The gap 131 and the insulating film 135 do not extend to the side of the second surface 11S2, which corresponds to the surface of the semiconductor substrate 11.

Similarly, the intra-pixel separation unit 14 has the first material layer 141 and the insulating film 145 provided between the first material layer 141 and the semiconductor substrate 11. The first material layer 141 and the insulating film 145 are provided to extend from the side of the first surface 11S1, which corresponds to the back surface of the semiconductor substrate 11, to a halfway position in the thickness direction (for example, the Z-axis direction) of the semiconductor substrate 11. The first material layer 141 and the insulating film 145 do not extend to the side of the second surface 11S2, which corresponds to the surface of the semiconductor substrate 11.

In a planar view, the structure of the unit pixel P in the imaging device 1D is the same as, for example, the structure of the unit pixel P in the imaging device 1 shown in FIGS. 3 and 4. Furthermore, in the second embodiment as well, the configurations of the first to third modified examples of the first embodiment are applicable. The unit pixel P in the imaging device 1D is not limited to the 2×2 type shown in FIGS. 3 and 4, but it may be, for example, of the 2×1 type shown in FIG. 8, the 3×3 type shown in FIG. 9, or the 4×4 type shown in FIG. 10.

The imaging device 1 D includes the inter-pixel separation unit 13 with the gap 131, the intra-pixel separation unit 14 with the first material layer 141, and the connection unit 15. As a result, like the imaging device 1, the imaging device 1D can prevent color mixing between the adjacent unit pixels P and suppress the reflection and scattering of light between the plurality of adjacent photoelectric conversion units 12 within the unit pixels P. Furthermore, in the imaging device 1D, the connection unit 15 connects the intra-pixel separation unit 14 of one adjacent unit pixel P and the intra-pixel separation unit 14 of the other adjacent unit pixel P. Therefore, even when the aspect ratio of the gap 131 increases, the collapse of the pattern can be suppressed.

### Third Embodiment

In the above first embodiment, it is described that the intra-pixel separation unit 14 (i.e., the same-color separation unit) has a lattice pattern in a plan view. In the embodiment of the present disclosure, the intra-pixel separation unit 14 in a lattice pattern may be configured such that the intersecting portion of the lattice and the linear portions of the lattice are made of different materials.

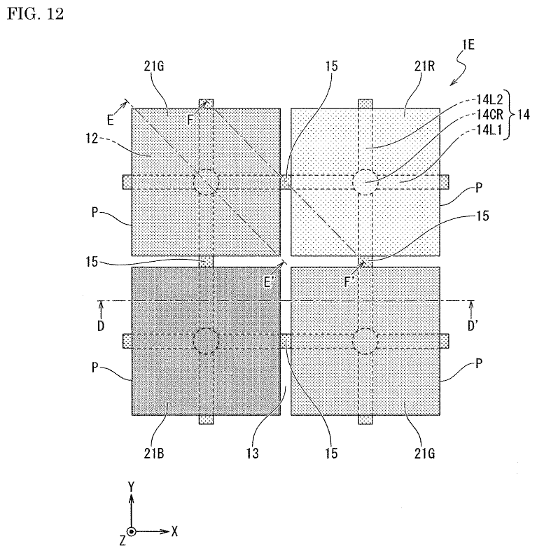

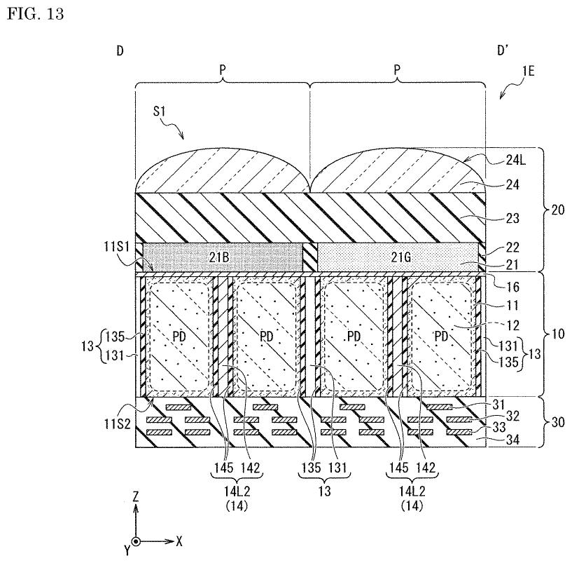

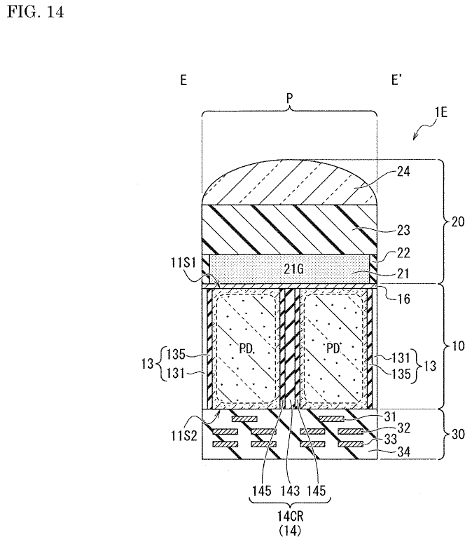

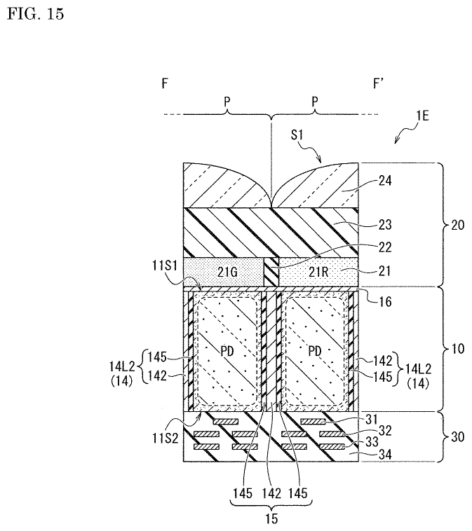

FIG. 12 is a plan view showing a configuration example of an imaging device 1E according to a third embodiment of the present disclosure. FIGS. 13 to 15 are cross-sectional views showing the configuration example of the imaging device 1E according to the third embodiment of the present disclosure. FIG. 13 is a cross-sectional view obtained by cutting the plan view shown in FIG. 12 along the line D-D′. FIG. 14 is a cross-sectional view obtained by cutting the plan view shown in FIG. 12 along the line E-E′. FIG. 15 is a cross-sectional view obtained by cutting the plan view shown in FIG. 12 along the line F-F′. Note that in FIG. 12, the illustration of the on-chip lenses 24 shown in FIGS. 13 to 15 is omitted.

As shown in FIG. 12, the intra-pixel separation unit 14 when viewed in a plane along the thickness direction (for example, the Z-axis direction) of the semiconductor substrate 11 has a first linear portion 14L1 that extends in the X-axis direction (an example of the “first direction” in the present disclosure), a second linear portion 14L2 that extends in the Y-axis direction (an example of the “second direction” in the present disclosure) orthogonal to the X-axis direction, and an intersecting portion 14CR that is positioned in the region where the first linear portion 14L1 and the second linear portion 14L2 intersect with each other. In the imaging device 1E, the first linear portion 14L1, the second linear portion 14L2, and the connection unit 15 are made of the same material. Furthermore, the intersecting portion 14CR is made of a material different from that of the first linear portion 14L1, the second linear portion 14L2, and the connection unit 15.

For example, the intra-pixel separation unit 14 has, as the first material layer, a second material layer 142 used in the first linear portion 14L1, the second linear portion 14L2, and the connection unit 15, and a third material layer 143 used in the intersecting portion 14CR. The second material layer 142 has a boron-doped amorphous silicon (BDAS) layer. The BDAS layer has a boron (B) concentration of, for example, 1×10¹⁸ cm⁻³ or more. As a result, the pinning of the trench sidewall where the first linear portion 14L1 and the second linear portion 14L2 are arranged can be enhanced.

Furthermore, the third material layer 143 has a material layer with a refractive index close to that of silicon (Si) constituting the semiconductor substrate 11, for example, at least one of a titanium oxide layer and an iron oxide layer. A difference in refractive index between the third material layer 143 and the semiconductor substrate 11 is greater than a difference in refractive index between the second material layer and the semiconductor substrate. As a result, even in the intersecting portion 14CR where the reflection and scattering of light are relatively likely to occur due to its structure, the reflection and scattering of light can be suppressed.

The imaging device 1E includes the inter-pixel separation unit 13 with the gap 131, the intra-pixel separation unit 14 with the second material layer 142 and the third material layer 143 as first material layer, and the connection unit 15. As a result, the imaging device 1E can prevent color mixing between the adjacent unit pixels P and suppress the reflection and scattering of light between the plurality of adjacent photoelectric conversion units 12 within the unit pixels P. Particularly, the first and second linear portions 14L1 and 14L2 of the intra-pixel separation unit 14 can reinforce the pinning of the trench sidewall, and the intersecting portion 14CR can suppress the reflection and scattering of light.

Furthermore, in the imaging device 1E, the connection unit 15 connects the intra-pixel separation unit 14 of one adjacent unit pixel P and the intra-pixel separation unit 14 of the other adjacent unit pixel P like the imaging device 1. Therefore, even when the aspect ratio of the gap 131 increases, the collapse of the pattern can be suppressed.

Note that in the third embodiment as well, the configurations of the first to third modified examples of the first embodiment are applicable. The unit pixel P in the imaging device 1E is not limited to the 2×2 type shown in FIGS. 3 and 4, but it may be, for example, of the 2×1 type shown in FIG. 8, the 3×3 type shown in FIG. 9, or the 4×4 type shown in FIG. 10.

### Fourth Embodiment

Next, as a fourth embodiment of the present disclosure, a manufacturing method for the inter-pixel separation unit 13, the intra-pixel separation unit 14, and the connection unit 15 of the imaging device 1 described in the first embodiment will be described. Note that the imaging device is manufactured using various devices such as a resist coating device, an exposure device, an etching device, an ion implantation device, and a film formation device. Hereinafter, these devices will collectively be referred to as a manufacturing device.

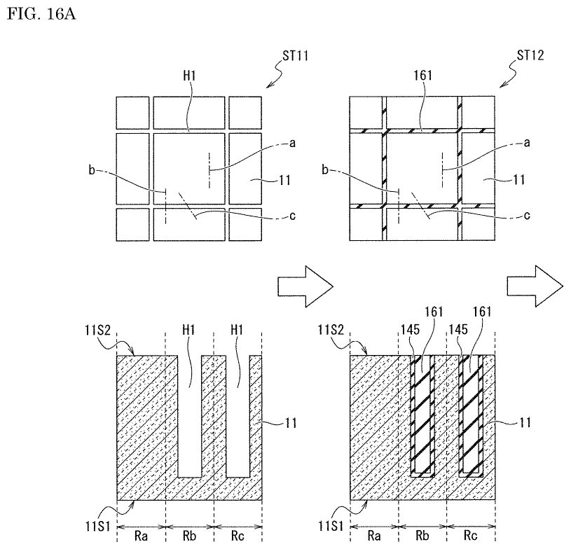

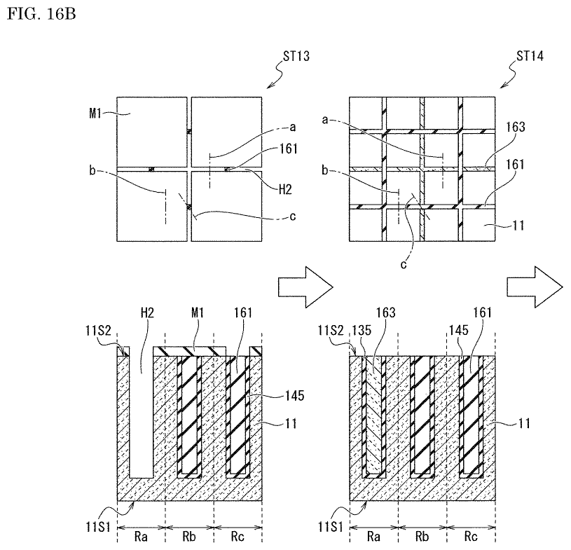

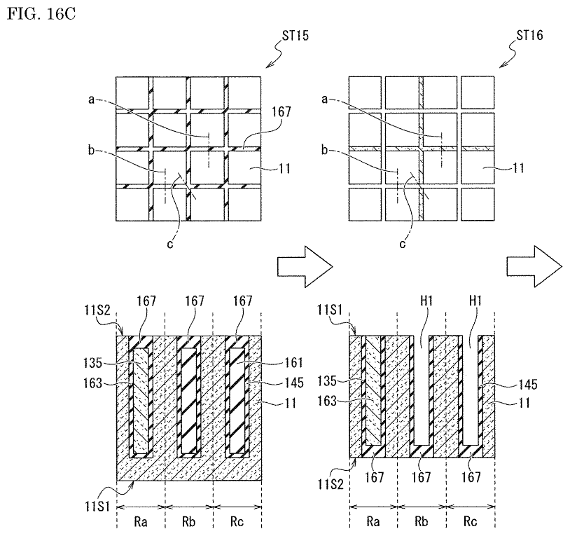

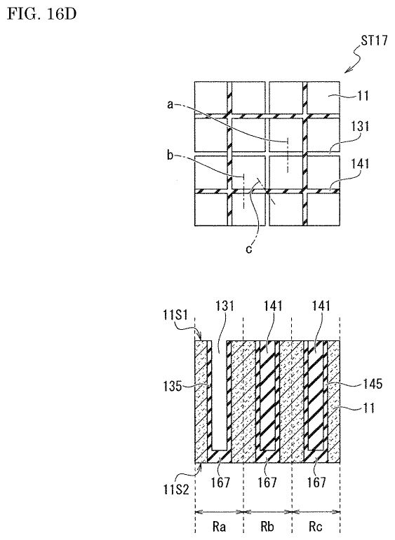

FIGS. 16A to 16D are views showing the manufacturing method for the imaging device according to the fourth embodiment of the present disclosure, in the order of steps. In steps ST11 to ST17 shown in FIGS. 16A to 16D, the upper figures are plan views, and the lower figures are cross-sectional views. In the upper plan views, an a-line is a line that intersects with the region where the inter-pixel separation unit 13 (different-color separation unit) in a lattice pattern is formed. A b-line is a line that intersects with the region where the intra-pixel separation unit 14 (same-color separation unit) in a lattice pattern is formed. A c-line is a line that intersects with the connecting direction in the region where the connection unit 15 that connects the intra-pixel separation units 14 (same-color separation units) between the adjacent unit pixels P is formed.

Furthermore, in steps ST11 to ST17 shown in FIGS. 16A to 16D, a region Ra in the lower cross-sectional views represents the region along the a-line, a region Rb represents the region along the b-line, and a region Rc represents the region along the c-line. Note that although the respective regions Ra, Rb, and Rc are arranged side by side in one direction in the lower cross-sectional views, this is merely a schematic representation due to space limitations. The respective regions Ra, Rb, and Rc are not actually arranged in one direction. The actual positions of the respective regions Ra, Rb, and Rc are the positions where they overlap with the a-line, the b-line, and the c-line shown in the upper plan views.

As shown in step ST11 in FIG. 16A, the manufacturing device partially etches the semiconductor substrate 11 from the side of the second surface 11S2, which is the surface of the semiconductor substrate 11, thereby forming slits H1. The slits H1 are formed in the region Rb where the intra-pixel separation unit 14 is formed and in the region Rc where the connection unit 15 is formed.

Next, the manufacturing device forms the insulating film 145 and a material film 161 in this order on the side of the second surface 11S2 of the semiconductor substrate 11, thereby filling the slits H1 in the regions Rb and Rc. As described above, the insulating film 145 serves as a pinning film on the slit sidewall. The material film 161 is preferably a material with the selectivity of dry etching with respect to silicon (Si), which constitutes the semiconductor substrate 11, and is preferably, for example, Si₃N₄ or SiO₂.

Next, the manufacturing device performs, for example, a CMP process on the side of the second surface 11S2 of the semiconductor substrate 11, thereby removing the material film 161 and the insulating film 145 from the second surface 11S2. As a result, as shown in step ST12 in FIG. 16A, the region Rb where the intra-pixel separation unit 14 is formed and the region Rc where the connection unit 15 is formed are filled with the material film 161 and the insulating film 145, while the material film 161 and the insulating film 145 are removed from the second surface 11S2 in the other regions.

Next, as shown in step ST13 in FIG. 16B, the manufacturing device forms a mask M1 on the second surface 11S2 of the semiconductor substrate 11. The mask M1 has a shape that covers the region Rb where the intra-pixel separation unit 14 is formed and exposes the region Rc where the connection unit 15 is formed and the region Ra where the inter-pixel separation unit 13 is formed. In other words, the mask M1 has a shape that covers the unit pixel P and exposes the adjacent unit pixels P. The material constituting the mask M1 is, for example, SiOx, SiNx, or amorphous carbon (a-C).

Next, the manufacturing device etches the region Ra exposed outside the mask M1, thereby forming a slit H2 in the region Ra. In this etching process, the semiconductor substrate 11 is wet-etched or dry-etched under the condition where the silicon constituting the semiconductor substrate 11 is easily etched, while the material film 161 and the insulating film 145 filling the region Rc, as well as the mask M1, are difficult to be etched. As a result, the slit H2 is formed in the region Ra. The material film 161 and the insulating film 145 in the region Rc exposed below the mask M1 are hardly etched and left in the slit H1.

Next, the manufacturing device forms the insulating film 135 and the material film 163 in this order on the side of the second surface 11S2 of the semiconductor substrate 11, thereby filling the slit H2 in the region Ra. The material film 163 is, for example, polysilicon (Poly-Si). Next, the manufacturing device performs, for example, a CMP process on the side of the second surface 11S2 of the semiconductor substrate 11, thereby removing the material film 163, the insulating film 135, and the mask M1 from the second surface 11S2. As a result, as shown in step ST14 in FIG. 16B, the region Ra where the inter-pixel separation unit 13 is formed is filled with the material film 163 and the insulating film 135, while the material film 163 and the insulating film 135 are removed from the second surface 11S2 in the other regions.

Next, the manufacturing device simultaneously (or separately) performs recessing on the material films 163 and 165 from the side of the second surface 11S2 of the semiconductor substrate 11. The recessing may be performed by etch-back. Next, in step ST15 in FIG. 16C, the manufacturing device fills the recess formed by the recessing with an insulating film 167. The insulating film 167 is, for example, SiOx or SiNx. Regarding the forming steps for the inter-pixel separation unit 13, the intra-pixel separation unit 14, and the connection unit 15, the FEOL (Front End of Line) process is completed.

Next, a back-surface process begins from step ST16 in FIG. 16C. In step ST16, the manufacturing device performs a wet etching process using an alkaline solution on the first surface 11S1, which is the back surface of the semiconductor substrate 11, thereby exposing the material films 161 and 163 on the side of the first surface 11S1. In the wet etching using the alkaline solution, silicon (Si) constituting the semiconductor substrate 11 is etched, while the material film 163 (for example, polysilicon) is difficult to be etched.

Next, the manufacturing device etches the material film 161 under the condition where the material film 161 is easily etched and the material film 164 and the semiconductor substrate 11 are difficult to be etched. As a result, the material film 161 is each removed from the slit H1 in the region Rb where the intra-pixel separation unit 14 is formed and from the slit H1 in the region Rc where the connection unit 15 is formed.

Next, as shown in step ST17 in FIG. 16D, the manufacturing device forms the first material layer 141 on the side of the first surface 11S1 of the semiconductor substrate 11, thereby filling the slits H1 in the regions Rb and Rc. As described above, the first material layer 141 is, for example, TiO₂ or Fe₂O₃.

Next, the manufacturing device performs, for example, a CMP process on the side of the first surface 11S1 of the semiconductor substrate 11, thereby removing the first material layer 141 from the first surface 11S1. As a result, the region Rb where the intra-pixel separation unit 14 is formed and the region Rc where the connection unit 15 is formed are filled with the first material layer 141, while the first material layer 141 is removed from the first surface 11S1 in the other regions.

Next, the manufacturing device etches and removes the material film 163 filled in the region Ra where the inter-pixel separation unit 13 is formed, thereby forming the gap 131. The material film 163 is, for example, polysilicon, and the first material layer 141 is, for example, TiO₂ or Fe₂O₃. Therefore, it is possible to remove the material film 163 by wet etching without etching the first material layer 141.

Through the above steps, the inter-pixel separation unit 13, the intra-pixel separation unit 14, and the connection unit 15 of the imaging device 1 described in the first embodiment are completed.

Furthermore, according to the manufacturing method of the fourth embodiment, in the FEOL process, the material film 161 is filled into each of the slits H1 in the region Rb where the intra-pixel separation unit 14 is formed and the region Rc where the connection unit is formed (step ST12). After that, in the back-surface process, the material film 161 is removed from inside of the slits H1 (step ST16), and the first material layer 141 is filled into the slits H1 from which the material film 161 has been removed. For example, compared to a case where the first material layer 141 is formed in the FEOL process instead of the back-surface process, the likelihood of contamination occurring in the first material layer 141 can be reduced.

When the first material layer 141 is formed in the FEOL process, it is necessary to select a high heat-resistant material for the first material layer 141, considering heat treatment temperature in the annealing process for the source, drain, or the like.

However, in the manufacturing method of the first embodiment, the first material layer 141 is formed in the back-surface process after the high-temperature annealing process. Therefore, a relatively low heat-resistant material can be used for the first material layer 141. The selection of materials for the first material layer 141 can be broadened.

### Modified Example of Fourth Embodiment

In the fourth embodiment, it is described that in the FEOL process, the material film 161 is once filled into each of the slits H1 in the region Rb where the intra-pixel separation unit 14 is formed and the region Rc where the connection unit is formed. Then, in the back-surface process, the material film 161 is removed, and the first material layer 141 is filled into the slits H1, thereby forming the intra-pixel separation unit 14 and the connection unit 15. However, in the embodiments of the present disclosure, the forming method for the intra-pixel separation unit 14 and the connection unit 15 is not limited to this.

### (1) First Modified Example

In the embodiments of the present disclosure, the material film 161 (for example, SiN or SiO₂) filled into each of the slits H1 in the regions Rb and Rc may be left as the first material layer in the FEOL process. In this case, the material film 161 is an example of the “first material layer” of the present disclosure.

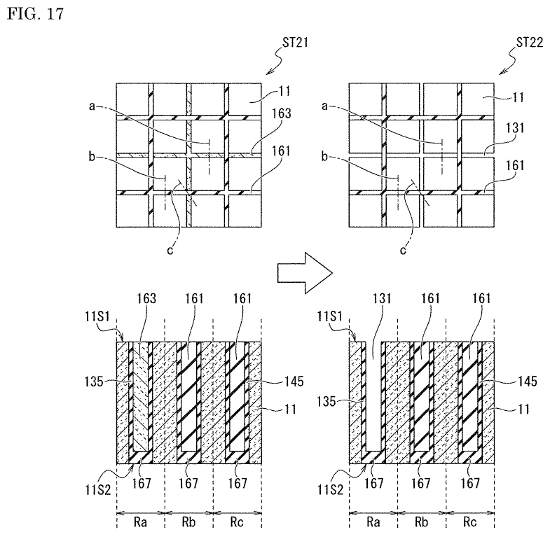

FIG. 17 is a view showing the manufacturing method for the imaging device according to a first modified example of the fourth embodiment of the present disclosure, in the order of steps. Like FIGS. 16A to 16D described above, in steps ST21 and ST22 shown in FIG. 17, the upper figures are plan views, and the lower figures are cross-sectional views. Until step ST21 in FIG. 17 where a wet etching process using an alkaline solution is performed on the first surface 11S1, which is the back surface of the semiconductor substrate 11, to expose the material films 161 and 163 on the side of the first surface 11S1, the same processes as those in step ST16 of the fourth embodiment are performed.

In the first modified example of the fourth embodiment, after exposing the material films 161 and 163 on the side of the first surface 11S1, the manufacturing device etches and removes the material film 163 filled into the region Ra, thereby forming the gap 131 as shown in step ST22 in FIG. 17. The material film 163 is, for example, polysilicon, and the first material layer 141 is, for example, TiO₂ or Fe₂O₃. Therefore, it is possible to remove the material film 163 by wet etching without etching the first material layer 141.

Through the above steps, the inter-pixel separation unit 13, the intra-pixel separation unit 14, and the connection unit 15 are completed. As described above, in this first modified example, the material film 161 left in the regions Rb and Rc is an example of the “first insulating film” of the present disclosure. According to this first modified example, the shortening and simplification of the manufacturing process are possible compared to the manufacturing method in the above fourth embodiment.

### (2) Second Modified Example

In the embodiments of the present disclosure, in the FEOL process, the first material layer 141, such as TiO₂ or Fe₂O₃, may be filled into each of the slits H1 in the regions Rb and Rc instead of the material film 161, such as SiN or SiO₂. As a result, the selection of materials for the first material layer 141 may be narrowed, or a reduction in the temperature of the thermal history may be required.

However, because the formation process of the material film 161 is not required, the shortening and simplification of the manufacturing process are possible.

Hereinafter, this second modified example will be described using the drawings in the order of steps.

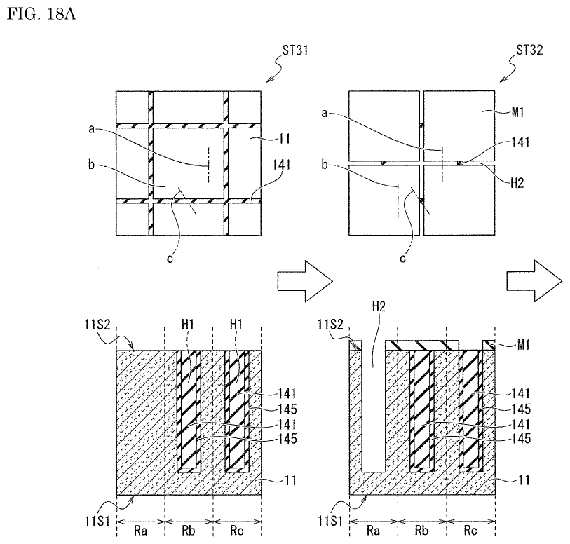

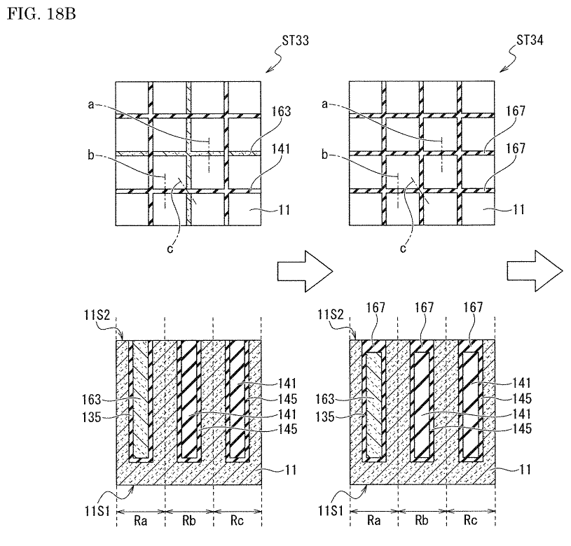

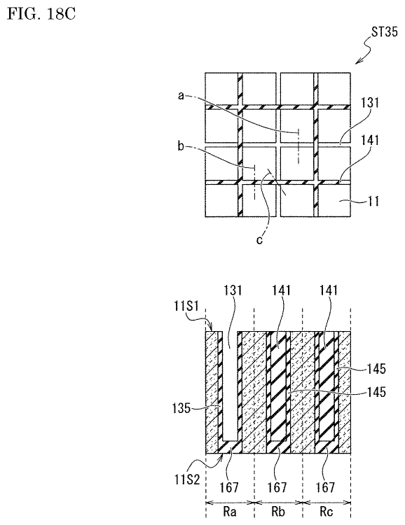

FIGS. 18A to 18C are views showing the manufacturing method for the imaging device according to the second modified example of the fourth embodiment of the present disclosure, in the order of steps. Like FIGS. 16A to 16D described above, in steps ST31 to ST35 shown in FIGS. 18A to 18C, the upper figures are plan views, and the lower figures are cross-sectional views. Until step ST31 in FIG. 18A where the slits H1 are formed in the regions Rb and Rc of the semiconductor substrate 11, the same processes as those in step ST16 of the fourth embodiment are performed.

Next, the manufacturing device forms the insulating film 145 and the first material layer 141 in this order on the side of the second surface 11S2 of the semiconductor substrate 11, thereby filling the slits H1 in the regions Rb and Rc. As described above, the first material layer 141 is, for example, TiO₂ or Fe₂O₃.

Next, the manufacturing device performs, for example, a CMP process on the side of the second surface 11S2 of the semiconductor substrate 11, thereby removing the first material layer 141 and the insulating film 145 from the second surface 11S2. As a result, as shown in step ST31 in FIG. 18A, the region Rb where the intra-pixel separation unit 14 is formed and the region Rc where the connection unit 15 is formed are filled with the first material layer 141 and the insulating film 145, while the first material layer 141 and the insulating film 145 are removed from the second surface 11S2 in the other regions.

Next, as shown in step ST32 in FIG. 18A, the manufacturing device forms the mask M1 on the second surface 11S2 of the semiconductor substrate 11. As described above, the mask M1 has a shape that covers the region Rb where the intra-pixel separation unit 14 is formed and exposes the region Rc where the connection unit 15 is formed and the region Ra where the inter-pixel separation unit 13 is formed. The material constituting the mask M1 is, for example, SiOx, SiNx, or amorphous carbon (a-C).

Next, the manufacturing device etches the region Ra exposed outside the mask M1, thereby forming the slit H2 in the region Ra. In this etching process, the semiconductor substrate 11 is wet-etched or dry-etched under the condition where silicon constituting the semiconductor substrate 11 is easily etched, while the first material layer 141 and the insulating film 145 filling the region Rc, as well as the mask M1, are difficult to be etched. As a result, the slit H2 is formed in the region Ra. The first material layer 141 and the insulating film 145 in the region Rc exposed below the mask M1 are hardly etched and left in the slit H1.

Next, the manufacturing device forms the insulating film 135 and the material film 163 in this order on the side of the second surface 11S2 of the semiconductor substrate 11, thereby filling the slit H2 in the region Ra. The material film 163 is, for example, polysilicon (Poly-Si). Next, the manufacturing device performs, for example, a CMP process on the side of the second surface 11S2 of the semiconductor substrate 11, thereby removing the material film 163, the insulating film 135, and the mask M1 from the second surface 11S2. As a result, as shown in step ST33 in FIG. 18B, the region Ra where the inter-pixel separation unit 13 is formed is filled with the material film 163 and the insulating film 135, while the material film 163 and the insulating film 135 are removed from the second surface 11S2 in the other regions.

Next, the manufacturing device simultaneously (or separately) performs recessing on the first material layer 141 and the material film 163 from the side of the second surface 11S2 of the semiconductor substrate 11. The recessing may be performed by etch-back. Next, as shown in step ST34 in FIG. 18B, the manufacturing device fills the recess formed by the recessing with the insulating film 167. The insulating film 167 is, for example, SiOx or SiNx. Regarding the forming steps for the inter-pixel separation unit 13, the intra-pixel separation unit 14, and the connection unit 15, the FEOL (Front End of Line) process is completed.

Next, a back-surface process begins from step ST35 in FIG. 18C. In step ST35, the manufacturing device performs a wet etching process using an alkaline solution on the first surface 11S1, which is the back surface of the semiconductor substrate 11, thereby exposing the first material layer 141 and the material film 163 on the side of the first surface 11S1. In the wet etching using the alkaline solution, silicon (Si) constituting the semiconductor substrate 11 is etched, while the first material layer 141 and the material film 163 (for example, polysilicon) are difficult to be etched.

Next, the manufacturing device etches and removes the material film 163 filled in the region Ra where the inter-pixel separation unit 13 is formed, thereby forming the gap 131. The material film 163 is, for example, polysilicon, and the first material layer 141 is, for example, TiO₂ or Fe₂O₃. Therefore, it is possible to remove the material film 163 by wet etching without etching the first material layer 141.

Through the above steps, the inter-pixel separation unit 13, the intra-pixel separation unit 14, and the connection unit 15 of the imaging device 1 described in the first embodiment are completed. According to this second modified example, because the process of filling the material film 161 into the slits H1 in the regions Rb and Rc, as well as the process of removing the material film 161, are not required, the shortening and simplification of the manufacturing process are possible.

### Fifth Embodiment

Next, as a fifth embodiment of the present disclosure, a manufacturing method for the inter-pixel separation unit 13, the intra-pixel separation unit 14, and the connection unit 15 of the imaging device 1D described in the second embodiment will be described.

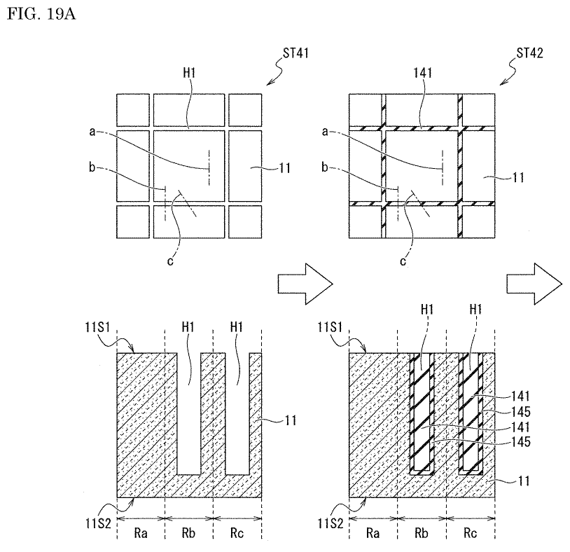

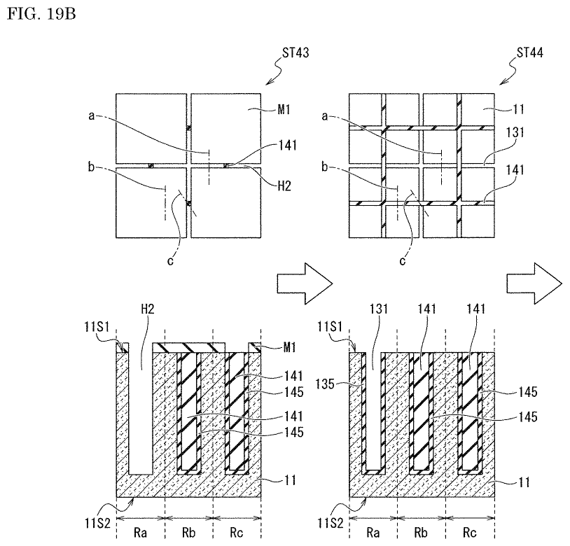

FIGS. 19A and 19B are views showing the manufacturing method for the imaging device according to the fifth embodiment of the present disclosure, in the order of steps. In steps ST41 to ST44 shown in FIGS. 19A and 19B, the upper figures are plan views, and the lower figures are cross-sectional views. Note that all steps ST41 to ST44 in FIG. 19A are back-surface processes.

As shown in step ST41 in FIG. 19A, the manufacturing device partially etches the semiconductor substrate 11 from the side of the first surface 11S1, which is the back surface of the semiconductor substrate 11, thereby forming the slits H1. The slits H1 are formed by the region Rb where the intra-pixel separation unit 14 is formed and the region Rc where the connection unit 15 is formed.

Next, the manufacturing device forms the insulating film 145 and the first material layer 141 in this order on the side of the first surface 11S1 of the semiconductor substrate 11, thereby filling the slits H1 in the regions Rb and Rc. The insulating film 145 is a pinning film and is, for example, a silicon oxide (SiOx) film, an aluminum oxide (AlOx) film, or a hafnium oxide (HfOx) film. The first material layer 141 is, for example, TiO₂ or Fe₂O₃.

Next, the manufacturing device performs, for example, a CMP process on the side of the first surface 11S1 of the semiconductor substrate 11, thereby removing the first material layer 141 and the insulating film 145 from the first surface 11S1. As a result, as shown in step ST42 in FIG. 19A, the region Rb where the intra-pixel separation unit 14 is formed and the region Rc where the connection unit 15 is formed are filled with the first material layer 141 and the insulating film 145, while the first material layer 141 and the insulating film 145 are removed from the first surface 11S1 in the other regions.

Next, as shown in step ST43 in FIG. 19B, the manufacturing device forms the mask M1 on the first surface 11S1 of the semiconductor substrate 11. The mask M1 has a shape that covers the region Rb where the intra-pixel separation unit 14 is formed and exposes the region Rc where the connection unit 15 is formed and the region Ra where the inter-pixel separation unit 13 is formed.

Next, the manufacturing device etches the region Ra exposed outside the mask M1, thereby forming the slit H2 in the region Ra. In this etching process, the semiconductor substrate 11 is wet-etched or dry-etched under the condition where silicon constituting the semiconductor substrate 11 is easily etched, while the first material layer 141 and the insulating film 145 filling the region Rc, as well as the mask M1, are difficult to be etched. As a result, the slit H2 is formed in the region Ra. The first material layer 141 and the insulating film 145 in the region Rc exposed below the mask M1 are hardly etched and left in the slit H1.

Next, the manufacturing device forms the insulating film 135 on the side of the first surface 11S1 of the semiconductor substrate 11, thereby covering the bottom surface and side surface of the slit H2 in the region Ra. The insulating film 135 is a pinning film and is, for example, a silicon oxide (SiOx) film, an aluminum oxide (AlOx) film, or a hafnium oxide (HfOx) film.

Next, the manufacturing device performs, for example, a CMP process on the side of the first surface 11S1 of the semiconductor substrate 11, thereby removing the insulating film 135 and the mask M1 from the first surface 11S1. As a result, as shown in step ST44 in FIG. 19B, the insulating film 135 is left in the region Ra where the inter-pixel separation unit 13 is formed, while the insulating film 135 is removed in the other regions.

Through the above steps, the inter-pixel separation unit 13, the intra-pixel separation unit 14, and the connection unit 15 of the imaging device 1D described in the second embodiment are completed. In the manufacturing method of the fifth embodiment, the first material layer 141 is formed in the back-surface process rather than in the FEOL process. Therefore, the likelihood of contamination occurring in the first material layer 141 can be reduced. Furthermore, a relatively low heat-resistant material can be used for the first material layer 141. Therefore, the selection of materials for the first material layer 141 can be broadened.

### Sixth Embodiment

Next, as a fifth embodiment of the present disclosure, a manufacturing method for the inter-pixel separation unit 13, the intra-pixel separation unit 14, and the connection unit 15 of the imaging device 1E described in the third embodiment will be described.

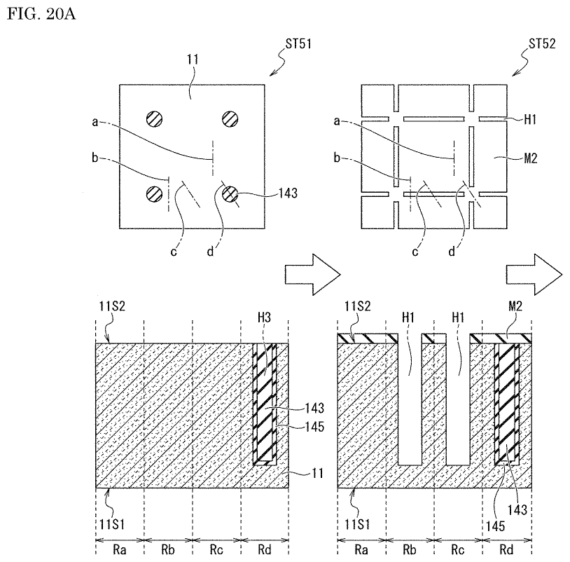

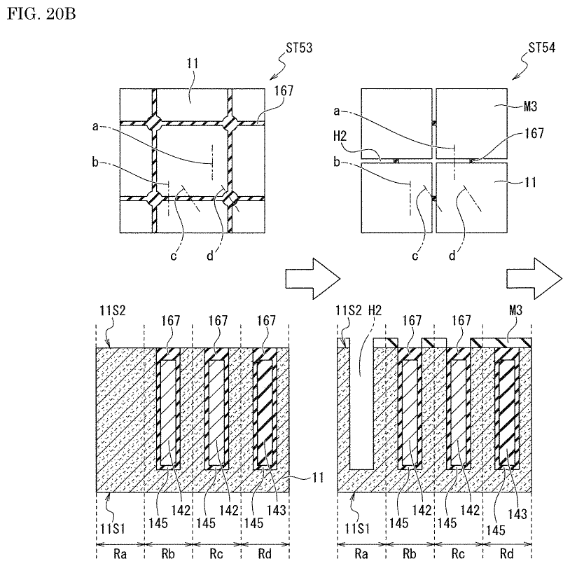

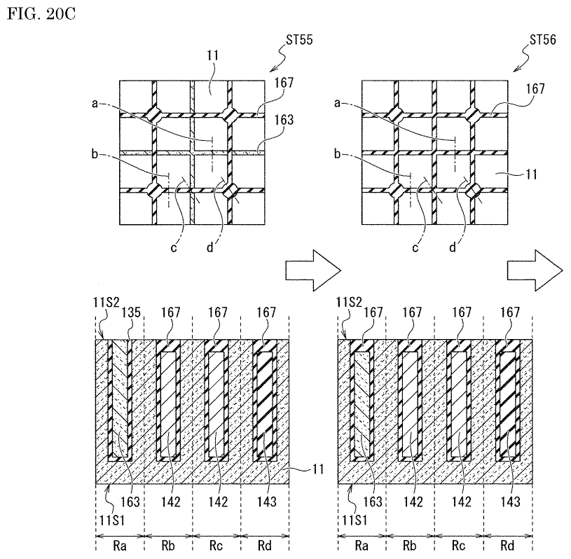

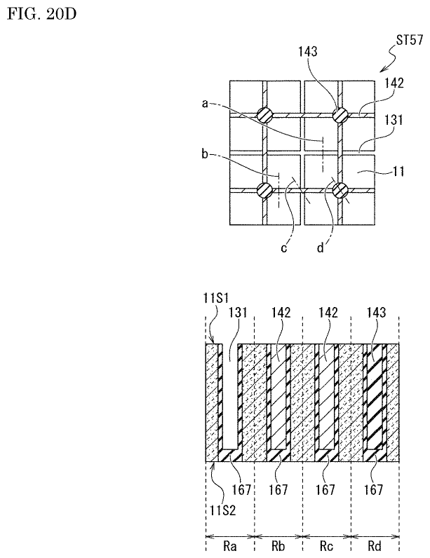

FIGS. 20A to 20D are views showing the manufacturing method for the imaging device according to the sixth embodiment of the present disclosure, in the order of steps. In steps ST51 to ST57 shown in FIGS. 20A and 20D, the upper figures are plan views, and the lower figures are cross-sectional views. In the upper plan views, a b-line is a line that intersects with the region where the first linear portion 14L1 of the intra-pixel separation unit 14 (same-color separation unit) in a lattice pattern is formed. The d-line is a line that intersects with the region where the intersecting portion 14CR of the intra-pixel separation unit 14 (same-color separation unit) in a lattice pattern is formed.

Furthermore, a region Rb in the lower cross-sectional views represents the region along the b-line, and a region Rd represents the region along the d-line. Note that although the regions Ra, Rb, Rc, and Rd are arranged side by side in one direction in the lower cross-sectional views, this is merely a schematic representation due to space limitations. The respective regions Ra, Rb, Rc, and Rd are not actually arranged in one direction. The actual positions of the respective regions Ra, Rb, Rc, and Rd are the positions where they overlap with the a-line, the b-line, the c-line, and the d-line shown in the upper plan views.

As shown in step ST51 in FIG. 20A, the manufacturing device partially etches the semiconductor substrate 11 from the side of the second surface 11S2, which is the surface of the semiconductor substrate 11, thereby forming a slit H3. The slit H3 is formed in a region Rd where an intersecting portion 14CR of the intra-pixel separation unit 14 (same-color separation unit) is formed.

Next, the manufacturing device forms the insulating film 145 and the third material layer 143 in this order on the side of the second surface 11S2 of the semiconductor substrate 11, thereby filling the slit H3 in the region Rd. As described above, the insulating film 145 serves as a pinning film on the slit sidewall and is, for example, a silicon oxide (SiOx) film, an aluminum oxide (AlOx) film, or a hafnium oxide (HfOx) film. The third material layer 143 is a material layer with a refractive index close to that of silicon (Si) constituting the semiconductor substrate 11 and is, for example, TiO₂ or Fe₂O₃.

Next, the manufacturing device performs, for example, a CMP process on the side of the second surface 11S2 of the semiconductor substrate 11, thereby removing the third material layer 143 and the insulating film 145 from the second surface 11S2. As a result, as shown in step ST51 in FIG. 20A, the region Rd where the intersecting portion 14CR of the intra-pixel separation unit 14 (same-color separation unit) is formed is filled with the third material layer 143 and the insulating film 145, while the third material layer 143 and the insulating film 145 are removed from the second surface 11S2 in the other regions.

Next, as shown in step ST52 in FIG. 20A, the manufacturing device forms the mask M2 on the second surface 11S2 of the semiconductor substrate 11. The mask M2 has a shape that covers the region Rd where the intersecting portion 14CR of the intra-pixel separation unit 14 is formed and the region Ra where the inter-pixel separation unit 13 is formed and exposes the region Rb where the linear portions (the first linear portion 14L1 and the second linear portion 14L2) of the intra-pixel separation unit 14 are formed and the region Rc where the connection unit 15 is formed. The material constituting the mask M2 is, for example, SiOx, SiNx, or amorphous carbon (a-C).

Next, the manufacturing device etches the regions Rb and Rc exposed outside the mask M2, thereby forming the slits H1 in the regions Rb and Rc.

Next, the manufacturing device forms the insulating film 145 and the second material layer 142 in this order on the side of the second surface 11S2 of the semiconductor substrate 11, thereby filling the slits H1 in the regions Rb and Rc. The insulating film 145 filled into the slits H1 is, for example, a pinning film with the same composition as that of the insulating film 145 filled into the slit H3. The second material layer 142 is a boron-doped amorphous silicon (BDAS) layer.

Next, the manufacturing device performs, for example, a CMP process on the side of the second surface 11S2 of the semiconductor substrate 11, thereby removing the second material layer 142, the insulating film 145, and the mask M2 from the second surface 11S2. As a result, the region Rb where the intra-pixel separation unit 14 is formed and the region Rc where the connection unit 15 is formed are filled with the second material layer 142 and the insulating film 145, while the second material layer 142 and the insulating film 145 are removed from the second surface 11S2 in the other regions.

Next, the manufacturing device simultaneously (or separately) recesses the second material layer 142 and the third material layer 143 from the side of the second surface 11S2 of the semiconductor substrate 11. The recessing may be performed by etch-back. Next, in step ST53 in FIG. 20B, the manufacturing device fills the recess formed by the recessing with the insulating film 167. The insulating film 167 is, for example, SiOx or SiNx.

Next, as shown in step ST54 in FIG. 20B, the manufacturing device forms a mask M3 on the second surface 11S2 of the semiconductor substrate 11. The mask M3 has a shape that covers the region Rb where the linear portion of the intra-pixel separation unit 14 is formed and the region Rd where the intersecting portion 14CR of the intra-pixel separation unit 14 is formed and exposes the region Ra where the inter-pixel separation unit 13 is formed and the region Rc where the connection unit 15 is formed. The material constituting the mask M3 is, for example, SiOx, SiNx, or amorphous carbon (a-C).

Next, the manufacturing device etches the region Ra exposed outside the mask M3, thereby forming the slit H2 in the region Ra.

Next, the manufacturing device forms the insulating film 135 and the material film 163 in this order on the side of the second surface 11S2 of the semiconductor substrate 11, thereby filling the slit H2 in the region Ra. The insulating film 135 filled into the slit H2 is a pinning film on the slit sidewall and is, for example, a silicon oxide (SiOx) film, an aluminum oxide (AlOx) film, or a hafnium oxide (HfOx) film. The material film 163 is, for example, polysilicon (Poly-Si).

The manufacturing device performs, for example, a CMP process on the side of the second surface 11S2 of the semiconductor substrate 11, thereby removing the material film 163, the insulating film 135, and the mask M3 from the second surface 11S2. As a result, as shown in step ST55 in FIG. 20C, the region Ra where the inter-pixel separation unit 13 is formed is filled with the material film 163 and the insulating film 145, while the material film 163 and the insulating film 145 are removed from the second surface 11S2 in the other regions.

Next, the manufacturing device performs recessing on the material film 163 from the side of the second surface 11S2 of the semiconductor substrate 11. The recessing may be performed by etch-back. Next, in step ST56 in FIG. 20C, the manufacturing device fills the insulating film 167 into the recesses formed by the recessing with the material film 163. The insulating film 167 filled into the region Ra is, for example, a film with the same composition as that of the insulating film 167 filled into the regions Rb, Rc, and Rd and is, for example, SiOx or SiNx.

Next, the manufacturing device performs a wet etching process using an alkaline solution on the first surface 11S1, which is the back surface of the semiconductor substrate 11, thereby exposing the second material layer 142, the third material layer 143, and the material film 163 on the side of the first surface 11S1. In the wet etching using the alkaline solution, silicon (Si) constituting the semiconductor substrate 11 is etched, while the material film 163 (for example, polysilicon) is difficult to be etched.

Next, as shown in step ST57 in FIG. 20D, the manufacturing device etches and removes the material film 163 filled into the region Ra where the inter-pixel separation unit 13 is formed, thereby forming the gap 131. The material film 163 is, for example, polysilicon, the second material layer 142 is a BDAS layer, and the third material layer 143 is, for example, TiO₂ or Fe₂O₃. Therefore, it is possible to remove the material film 163 by wet etching without etching the second material layer 142 and the third material layer 143.

Through the above steps, the inter-pixel separation unit 13, the intra-pixel separation unit 14, and the connection unit 15 of the imaging device 1E described in the third embodiment are completed.

### APPLICATION EXAMPLES

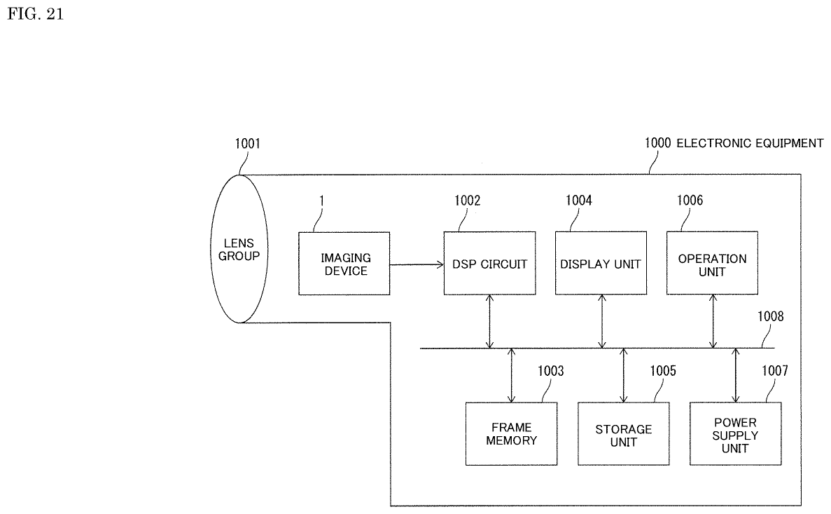

The above imaging device 1 and the like can be applied to, for example, any type of electronic equipment with an imaging function, such as camera systems like digital still cameras and video cameras, as well as mobile phones with an imaging function. FIG. 21 shows a schematic configuration of electronic equipment 1000.

The electronic equipment 1000 has, for example, a lens group 1001, the imaging device 1, a DSP (Digital Signal Processor) circuit 1002, a frame memory 1003, a display unit 1004, a recording unit 1005, an operation unit 1006, and a power supply unit 1007, all of which are connected to each other via a bus line 1008.

The lens group 1001 takes in incident light (image light) from a subject and forms an image on the imaging surface of the imaging device 1. The imaging device 1 converts the amount of the incident light, which is formed on the imaging surface by the lens group 1001, into electrical signals for each pixel and supplies the converted electrical signals to the DSP circuit 1002 as pixel signals.

The DSP circuit 1002 is a signal processing circuit that processes the signals supplied from the imaging device 1. The DSP circuit 1002 outputs the image data obtained by processing the signals from the imaging device 1. The frame memory 1003 temporarily retains the image data processed by the DSP circuit 1002 for each frame.

The display unit 1004 is composed of, for example, a panel-type display device such as a liquid crystal panel or an organic EL (Electro Luminescence) panel and records image data of moving images or still images captured by the imaging device 1 on recording media such as semiconductor memories or hard disks.

The operation unit 1006 outputs operation signals for various functions of the electronic equipment 1000 in response to user operations. The power supply unit 1007 appropriately supplies various power supplies, which serve as operation power for the DSP circuit 1002, the frame memory 1003, the display unit 1004, the recording unit 1005, and the operation unit 1006, to these supply targets.

### APPLIED EXAMPLES

### (Applied Examples to Moving Bodies)

The technology of the present disclosure (the present technology) can be applied to various products. For example, the technology according to the present disclosure may be implemented as a device mounted on any type of moving bodies, such as automobiles, electric vehicles, hybrid electric vehicles, motorcycles, bicycles, personal mobility devices, airplanes, drones, ships, or robots.

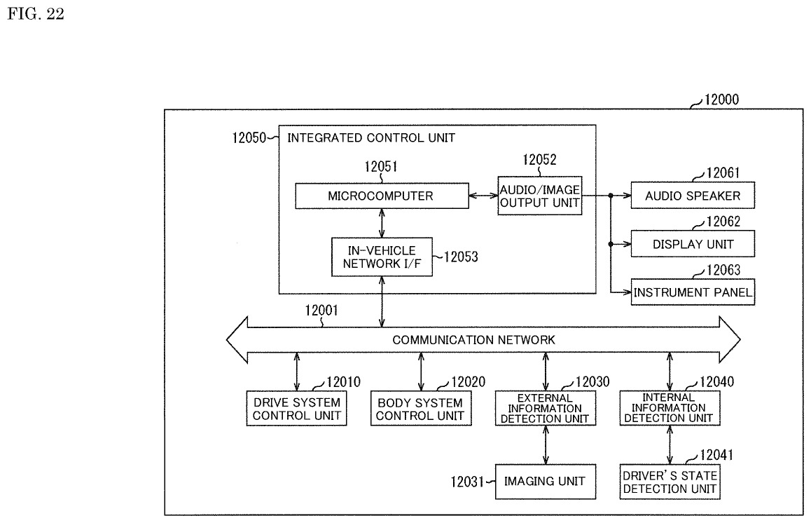

FIG. 22 is a block diagram showing a schematic configuration example of a vehicle control system, which is an example of a moving body control system to which the technology according to the present disclosure can be applied.

A vehicle control system 12000 includes a plurality of electronic control units connected via a communication network 12001. In the example shown in FIG. 22, the vehicle control system 12000 includes a drive system control unit 12010, a body system control unit 12020, an external information detection unit 12030, an internal information detection unit 12040, and an integrated control unit 12050. Furthermore, as the functional configuration of the integrated control unit 12050, a microcomputer 12051, an audio/image output unit 12052, and an in-vehicle network I/F (interface) 12053 are shown.

The drive system control unit 12010 controls the operation of a device related to a vehicle drive system according to various programs. For example, the drive system control unit 12010 functions as a control device, such as a driving force generation device for generating the driving force for the vehicle, like an internal combustion engine or a driving motor, a driving force transmission mechanism for transmitting the driving force to the wheels, a steering mechanism for adjusting the steering angle of the vehicle, and a braking device for generating the braking force for the vehicle.

The body system control unit 12020 controls the operations of various devices mounted in the vehicle body according to various programs. For example, the body system control unit 12020 functions as a control device for a keyless entry system, a smart key system, a power window device, or various lamps including a headlamp, a backup light, a brake light, a turn signal, a fog light, and the like. In this case, radio waves emitted from a portable device that substitutes for a key, or signals from various switches, can be input to the body system control unit 12020. The body system control unit 12020 receives the input of these radio waves or signals and controls the vehicle's door lock device, power window device, lamps, and the like.

The external information detection unit 12030 detects external information of the vehicle in which the vehicle control system 12000 is mounted. For example, the external information detection unit 12030 is connected to the imaging unit 12031. The external information detection unit 12030 causes the imaging unit 12031 to capture images of the outside of the vehicle and receives the captured images. The external information detection unit 12030 may perform object detection processing or distance detection processing on persons, cars, obstacles, signs, letters on the road, or the like on the basis of the received images.

The imaging unit 12031 is an optical sensor that receives light and outputs the electrical signals corresponding to the amount of the received light. The imaging unit 12031 can also output the electrical signals as images or as ranging information. Furthermore, the light received by the imaging unit 12031 may be visible light or invisible light such as infrared light.

The internal information detection unit 12040 detects information on the inside of the vehicle. The internal information detection unit 12040 is connected to, for example, a driver's state detection unit 12041 that detects the state of a driver. The driver's state detection unit 12041 includes, for example, a camera that captures images of the driver. The internal information detection unit 12040 may calculate a driver's fatigue degree or a concentration degree or may determine whether the driver is dozing at the wheel on the basis of detected information input from the driver's state detection unit 12041.

The microcomputer 12051 can compute control target values for the driving force generation device, the steering mechanism, or the braking device on the basis of the information on the outside or the inside of the vehicle acquired by the external information detection unit 12030 or the internal information detection unit 12040 and output control instructions to the drive system control unit 12010. For example, the microcomputer 12051 can perform cooperative control to implement the functions of an ADAS (Advanced Driver Assistance System), such as vehicle collision avoidance or impact mitigation, following driving based on an inter-vehicle distance, vehicle speed maintenance driving, vehicle collision warning, vehicle lane deviation warning, or the like.

Furthermore, the microcomputer 12051 can perform cooperative control for automated driving or the like in which autonomous driving is performed without relying on driver's operations, by controlling the driving force generation device, the steering mechanism, the braking device, or the like, on the basis of the surrounding information on the vehicle acquired by the external information detection unit 12030 or the internal information detection unit 12040.

Furthermore, the microcomputer 12051 can output control instructions to the body system control unit 12020 on the basis of the information on the outside of the vehicle acquired by the external information detection unit 12030. For example, the microcomputer 12051 can perform cooperative control to prevent glare, such as switching from a high beam to a low beam, by controlling the headlamp according to the positions of preceding vehicles or oncoming vehicles detected by the external information detection unit 12030.

The audio/image output unit 12052 transmits output signals for at least one of audio and images to output devices capable of visually or audibly notifying passengers or the outside of the vehicle of information. In the example of FIG. 22, an audio speaker 12061, a display unit 12062, and an instrument panel 12063 are shown as the output devices. The display unit 12062 may include, for example, at least one of an on-board display and a head-up display.

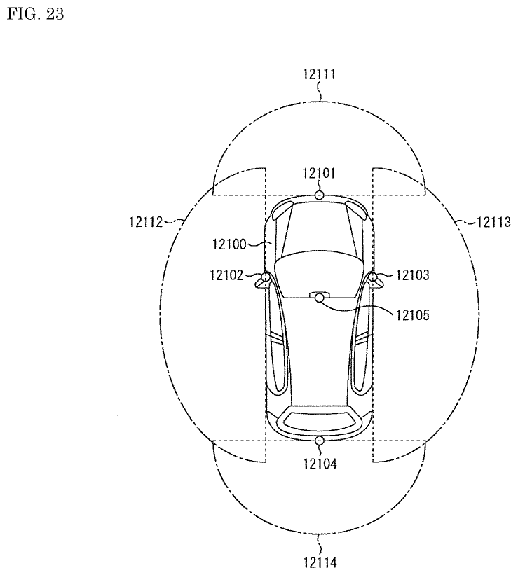

FIG. 23 is a diagram showing an example of the installation position of the imaging unit 12031.

In FIG. 23, a vehicle 12100 has imaging units 12101, 12102, 12103, 12104, and 12105 as the imaging unit 12031.

The imaging units 12101, 12102, 12103, 12104, and 12105 are provided, for example, at positions such as the front nose, side mirrors, rear bumper, back door of the vehicle 12100, and the upper portion of the windshield inside of the vehicle. The imaging unit 12101 provided at the front nose and the imaging unit 12105 provided at the upper portion of the windshield inside of the vehicle mainly capture images of the front side of the vehicle 12100. The imaging units 12102 and 12103 provided at the side mirrors mainly capture images of the lateral sides of the vehicle 12100. The imaging unit 12104 provided at the rear bumper or the back door mainly captures images of the rear side of the vehicle 12100. The images of the front side captured by the imaging units 12101 and 12105 are mainly used for detecting preceding vehicles, pedestrians, obstacles, traffic lights, traffic signs, lanes, and the like.

Note that FIG. 23 shows examples of the imaging ranges of the imaging units 12101 to 12104. An imaging range 12111 shows the imaging range of the imaging unit 12101 provided at the front nose, imaging ranges 12112 and 12113 show the imaging ranges of the imaging units 12102 and 12103 provided at the side mirrors, respectively, and an imaging range 12114 shows the imaging range of the imaging unit 12104 provided at the rear bumper or the back door. For example, a bird's-eye view of the vehicle 12100 seen from the above is obtained by superimposing image data captured by the imaging units 12101 to 12104.

At least one of the imaging units 12101 to 12104 may have a function to acquire distance information. For example, at least one of the imaging units 12101 to 12104 may be a stereo camera composed of a plurality of imaging elements or may be an imaging element that has pixels for phase difference detection.

For example, by calculating the distance to each three-dimensional object in the imaging ranges 12111 to 12114 and the temporal change of this distance (the relative speed with respect to the vehicle 12100) on the basis of the distance information obtained from the imaging units 12101 to 12104, the microcomputer 12051 can extract, particularly, the closest three-dimensional object that is on the traveling path of the vehicle 12100 and travels at a specified speed (for example, 0 km/h or higher) in substantially the same direction as the vehicle 12100, as a preceding vehicle. Moreover, the microcomputer 12051 can set an inter-vehicle distance that should be secured in advance before reaching a preceding vehicle and can perform automated braking control (including following stop control), automated acceleration control (including following start control), and the like. As described above, cooperative control can be performed for automated driving or the like in which autonomous traveling is performed without relying on driver's operations.

For example, on the basis of the distance information obtained from the imaging units 12101 to 12104, the microcomputer 12051 can classify and extract three-dimensional object data regarding three-dimensional objects into categories such as two-wheeled vehicles, normal vehicles, large vehicles, pedestrians, and other three-dimensional objects like electric poles, and use them for automatic obstacle avoidance. For example, the microcomputer 12051 differentiates surrounding obstacles of the vehicle 12100 into those visible to the driver of the vehicle 12100 and those difficult to view. Then, the microcomputer 12051 determines collision risk, which indicates the degree of risk of collision with each obstacle. When the collision risk reaches a setting value or higher, which indicates potential collision, the microcomputer 12051 can perform driving support for collision avoidance by outputting an alert to the driver through the audio speaker 12061 or the display unit 12062, or by performing forced deceleration or avoidance steering through the drive system control unit 12010.

At least one of the imaging units 12101 to 12104 may be an infrared camera that detects infrared rays. For example, the microcomputer 12051 can recognize pedestrians by determining whether the pedestrians exist in captured images of the imaging units 12101 to 12104. Such recognition of pedestrians is performed, for example, by the procedure of extracting feature points from the captured images of the imaging units 12101 to 12104, which serve as infrared cameras, as well as by the procedure of performing pattern matching processing on a series of feature points that indicate the outlines of objects and determining whether the objects are the pedestrians. When the microcomputer 12051 determines that pedestrians exist in captured images of the imaging units 12101 to 12104 and recognizes the pedestrians, the audio/image output unit 12052 controls the display unit 12062 to superimpose and display square contour lines to emphasize the recognized pedestrians. Furthermore, the audio/image output unit 12052 may control the display unit 12062 to display icons or the like indicating pedestrians at desired positions.

An example of the moving body control system to which the technology according to the present disclosure can be applied has been described above. Among the configurations described above, the technology according to the present disclosure can be applied to the imaging unit 12031. Specifically, the imaging device 1 and the like can be applied to the imaging unit 12031. The application of the technology according to the present disclosure to the imaging unit 12031 enables the acquisition of high-definition captured images with enhanced optical characteristics. Therefore, in moving body control systems, high-accuracy control can be performed using captured images.

### (Applied Example to Endoscopic Surgery System)

The technology according to the present disclosure (the present technology) can be applied to various products. For example, the technology according to the present disclosure may be applied to endoscopic surgery systems.

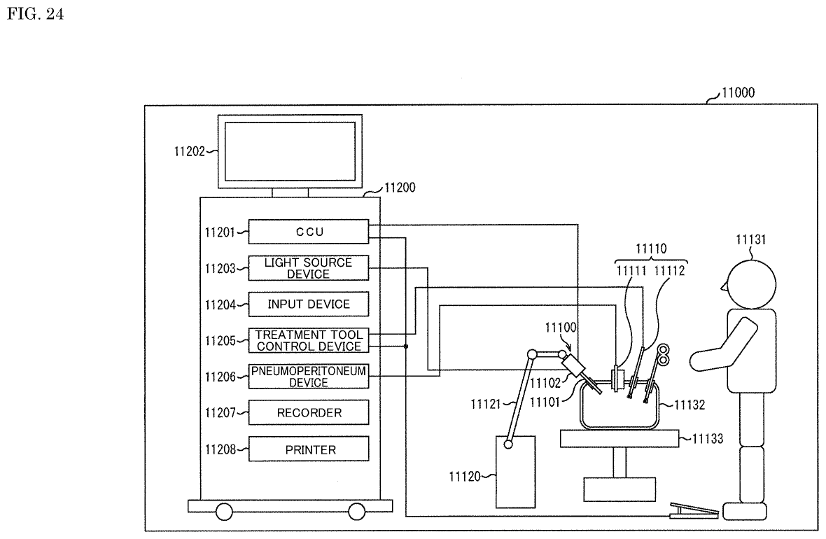

FIG. 24 is a diagram showing an example of the schematic configuration of an endoscopic surgery system to which the technology according to the present disclosure (the present technology) can be applied.

FIG. 24 shows a state where a surgeon (doctor) 11131 is performing a surgical operation on a patient 11132 on a patient bed 11153 using an endoscopic surgery system 11000. As shown in the figure, the endoscopic surgery system 11000 is composed of an endoscope 11100, other surgical instruments 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 is composed of a lens barrel 11101 with a specified-length region from its distal end inserted into the body cavity of the patient 11132, and a camera head 11102 connected to the base end of the lens barrel 11101. In the shown example, the endoscope 11100 is configured as a so-called rigid endoscope with the rigid lens barrel 11101. However, the endoscope 11100 may also be configured as a so-called flexible endoscope with a flexible lens barrel.

The lens barrel 11101 has an opening at the distal end, where an objective lens is fit. The endoscope 11100 is connected to a light source device 11203. The light generated by the light source device 11203 is guided to the distal end of the lens barrel by a light guide extended inside of the lens barrel 11101 and irradiated toward an observation target inside of the body cavity of the patient 11132 through the objective lens. Note that the endoscope 11100 may be a direct-viewing endoscope, an oblique-viewing endoscope, or a side-viewing endoscope.

An optical system and an imaging element are provided inside of the camera head 11102. Reflected light (observation light) from the observation target is focused onto the imaging element by the optical system. When the observation light is photoelectrically converted by the imaging element, an electrical signal corresponding to the observation light, that is, an image signal corresponding to an observation image is formed. The image signal is transmitted as RAW data to a camera control unit (CCU: Camera Control Unit) 11201.

The CCU 11201 is composed of a CPU (Central Processing Unit), a GPU (Graphics Processing Unit), and the like and comprehensively controls the operations of the endoscope 11100 and a display device 11202. Moreover, the CCU 11201 receives an image signal from the camera head 11102 and performs various image processing, such as development processing (demosaic processing), on the image signal to display an image based on the image signal.

The display device 11202 displays the image based on the image signal subjected to the image processing by the CCU 11201, under the control of the CCU 11201.

The light source device 11203 is composed of, for example, a light source such as an LED (Light Emitting Diode) and supplies irradiation light to the endoscope 11100 to capture an image of a surgical site or the like.

An input device 11204 is an input interface for the endoscopic surgery system 11000. The user can input various information or instructions to the endoscopic surgery system 11000 via the input device 11204. For example, the user inputs instructions to change the imaging conditions of the endoscope 11100 (the type of irradiation light, magnification, focal length, or the like).

A treatment tool control device 11205 controls the driving of the energy treatment tool 11112 to cauterize or incise tissues, or to seal blood vessels or the like. A pneumoperitoneum device 11206 delivers gas into the body cavity of the patient 11132 via the pneumoperitoneum tube 11111 to inflate the body cavity for the purpose of securing a field of view through the endoscope 11100 and providing workspace for the surgeon. A recorder 11207 is a device capable of recording various surgical information. A printer 11208 is a device capable of printing various surgical information in various formats, such as text, images, and graphs.

Note that the light source device 11203, which supplies irradiation light to the endoscope 11100 to capture an image of a surgical site, can be composed of, for example, an LED, a laser light source, or a white light source formed by a combination of these components. When the white light source is formed by a combination of RGB laser light sources, the output intensity and the output timing of each color (each wavelength) can be controlled with high accuracy. Therefore, the light source device 11203 can adjust the white balance of the captured image. Furthermore, in this case, by irradiating the observation target with laser light from each of the RGB laser light sources in a time-sharing manner and controlling the driving of the imaging element of the camera head 11102 in synchronization with the irradiation timing, it is also possible to capture images corresponding to each of the RGB in a time-sharing manner. According to this method, color images can be obtained without providing a color filter in the imaging element.

Furthermore, the driving of the light source device 11203 may be controlled such that the intensity of the output light changes at each specified time. By controlling the driving of the imaging element of the camera head 11102 in synchronization with the timing of the change in the light intensity to acquire images in a time-sharing manner and combining these images, a high dynamic range image without so-called blackouts and whiteouts can be generated.

Furthermore, the light source device 11203 may be configured to be capable of supplying light in a specified wavelength band corresponding to special light observation. In the special light observation, for example, so-called narrow band light observation (Narrow Band Imaging) is performed where light in a band narrower than that of irradiation light (that is, white light) during normal observation is irradiated using the wavelength dependence of light absorption in body tissues, thereby imaging specified tissues such as blood vessels in a mucous membrane surface layer with high contrast. Alternatively, in the special light observation, fluorescence observation may be performed where images are obtained by fluorescence generated by the irradiation of excitation light. In the fluorescence observation, it is possible to perform observing fluorescence from body tissues by irradiating the body tissues with excitation light (autofluorescence observation), locally injecting a reagent such as indocyanine green (ICG) into body tissues and irradiating the body tissues with excitation light corresponding to the fluorescence wavelength of the reagent to obtain a fluorescence image, or the like. The light source device 11203 can be configured to be capable of supplying narrow band light and/or excitation light corresponding to such special light observation.

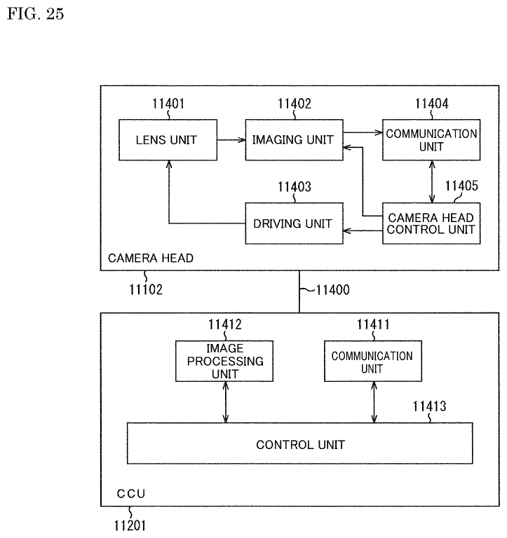

FIG. 25 is a block diagram showing examples of the functional configurations of the camera head 11102 and the CCU 11201 shown in FIG. 24.

The camera head 11102 has a lens unit 11401, an imaging unit 11402, a driving unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other via a transmission cable 11400.

The lens unit 11401 is an optical system provided at the portion connected to the lens barrel 11101. The observation light taken in from the distal end of the lens barrel 11101 is guided to the camera head 11102 and is incident on the lens unit 11401. The lens unit 11401 is configured by a combination of a plurality of lenses including a zoom lens and a focus lens.

The imaging unit 11402 is composed of an imaging element. The imaging unit 11402 may be composed of one element (a so-called single-plate type) or a plurality of elements (a so-called multi-plate type). When the imaging unit 11402 is configured as a multi-plate type, for example, an image signal corresponding to each of RGB is generated by each imaging element, and a color image may be obtained by synthesizing these image signals. Alternatively, the imaging unit 11402 may be configured to have a pair of imaging elements to acquire respective image signals for the right eye and the left eye, corresponding to three-dimensional (3D) display. The provision of 3D display allows the surgeon 11131 to more accurately recognize the depth of living tissues in a surgical site. Note that when the imaging unit 11402 is configured as a multi-plate type, a plurality of systems of lens units 11401 can be provided, each corresponding to each imaging element.

Furthermore, the imaging unit 11402 may not necessarily be provided in the camera head 11102. For example, the imaging unit 11402 may be provided immediately after the objective lens inside of the lens barrel 11101.

The driving unit 11403 is composed of an actuator and moves the zoom lens and the focus lens of the lens unit 11401 by a specified distance along the optical axis under the control of the camera head control unit 11405. As a result, the magnification and focus of the image captured by the imaging unit 11402 can be adjusted appropriately.

The communication unit 11404 is composed of a communication device used to exchange various information with the CCU 11201. The communication unit 11404 transmits the image signal obtained from the imaging unit 11402 as RAW data to the CCU 11201 via the transmission cable 11400.

Furthermore, the communication unit 11404 receives a control signal used to control the driving of the camera head 11102 from the CCU 11201 and supplies the received control signal to the camera head control unit 11405. The control signal includes, for example, information regarding imaging conditions, such as information indicating the designation of the frame rate of a captured image, information indicating the designation of an exposure value during image capturing, and/or information indicating the designation of the magnification and focus of a captured image.

Note that the above imaging conditions, such as the frame rate, the exposure value, the magnification, and the focus, may be appropriately specified by the user, or may be automatically set by the control unit 11413 of the CCU 11201 on the basis of the acquired image signal. In the latter case, a so-called AE (Auto Exposure) function, a so-called AF (Auto Focus) function, and a so-called AWB (Auto White Balance) function are installed in the endoscope 11100.

The camera head control unit 11405 controls the driving of the camera head 11102 on the basis of the control signal from the CCU 11201 received via the communication unit 11404.

The communication unit 11411 is composed of a communication device used to transmit and receive various information to and from the camera head 11102. The communication unit 11411 receives the image signal transmitted via the transmission cable 11400 from the camera head 11102.

Furthermore, the communication unit 11411 transmits the control signal used to control the driving of the camera head 11102 to the camera head 11102. The image signal and the control signal can be transmitted through electric communication, optical communication, or the like.

The image processing unit 11412 performs various image processing on the image signal, which is the RAW data transmitted from the camera head 11102.

The control unit 11413 performs various control related to the imaging of a surgical site or the like by the endoscope 11100 and the display of the captured images obtained through the imaging of surgical site or the like. For example, the control unit 11413 generates control signals used to control the driving of the camera head 11102.

Furthermore, the control unit 11413 causes the display device 11202 to display a captured image where a surgical site or the like is reflected, on the basis of an image signal that has been subjected to the image processing by the image processing unit 11412. At this time, the control unit 11413 may recognize various objects in the captured image using various image recognition technologies. For example, by detecting the shape, color, or the like of the edge of an object included in the captured image, the control unit 11413 can recognize a surgical instrument such as forceps, a specific biological site, bleeding, mist generated during the use of the energy treatment tool 11112, or the like. When the control unit 11413 causes the captured image to be displayed on the display device 11202, the control unit 11413 may cause various surgery support information to be superimposed on the image of the surgical site and displayed using a result of the recognition. When surgery support information is displayed in a superimposed manner and is presented to the surgeon 11131, it becomes possible to reduce the burden on the surgeon 11131 and enable the surgeon 11131 to reliably perform a surgical operation.

The transmission cable 11400 that connects the camera head 11102 and the CCU 11201 is an electrical signal cable that supports the communication of electrical signals, an optical fiber that supports optical communication, or a composite cable of these materials.

In the example shown, wired communication is performed using the transmission cable 11400. Wireless communication may also be performed between the camera head 11102 and the CCU 11201.

An example of the endoscopic surgery system to which the technology according to the present disclosure can be applied has been described. Among the configurations described above, the technology according to the present disclosure can be suitably applied to the imaging unit 11402 provided in the camera head 11102 of the endoscope 11100. The application of the imaging device 1 and the like according to the present disclosure to the imaging unit 11402 enables the enhancement of the optical characteristics of the imaging unit 11402. Therefore, the high-definition endoscope 11100 can be provided.

### OTHER EMBODIMENTS

As described above, the present disclosure has been described on the basis of the embodiments, modified examples, application examples, and applied examples. However, the descriptions and drawings that form part of the present disclosure should not be understood as limiting the present disclosure. Various alternative embodiments, examples, and operational technologies will be apparent to those skilled in the art from the present disclosure. For example, the application of the technology according to the present disclosure is not limited to imaging devices such as CMOS image sensors, but the technology may be applied to, for example, ranging devices such as direct ToF (Time of Flight) sensors and indirect ToF sensors. In other words, the light detection device of the present disclosure may be not only an imaging device but also a ranging device. It goes without saying that the present technology includes various embodiments and the like that are not described herein. At least one of the various omissions, replacements, or modifications of the constituting elements can be made without departing from the essence of the above-described embodiments and modified examples. Furthermore, the effects described in the present specification are merely exemplary and not intended to be limiting. Other effects may also be possible.

Note that the present disclosure can also employ the following configurations.

(1)

A light detection device including:
a semiconductor substrate having a first surface and a second surface positioned on a side opposite to the first surface, the semiconductor substrate having a plurality of unit pixels arranged in a matrix pattern and, for each of the unit pixels, a plurality of photoelectric conversion units configured to generate charges corresponding to a light receiving amount through photoelectric conversion;
an inter-pixel separation unit provided between the adjacent unit pixels, the inter-pixel separation unit having a gap configured to electrically and optically separate the adjacent unit pixels;
an intra-pixel separation unit provided between the adjacent photoelectric conversion units within the unit pixels, the intra-pixel separation unit having a first material layer configured to electrically separate the adjacent photoelectric conversion units; and
a connection unit provided between the adjacent unit pixels, the connection unit configured to connect the intra-pixel separation unit of one adjacent unit pixel and the intra-pixel separation unit of the other adjacent unit pixel.
   (2)

The light detection device according to (1), wherein the gap is provided to extend from one of the first surface and the second surface to at least a halfway position in a thickness direction of the semiconductor substrate.

(3)

The light detection device according to (1) or (2), wherein the intra-pixel separation unit has a first insulating film provided between the gap and the semiconductor substrate.

(4)

The light detection device according to any one of (1) to (3), wherein the intra-pixel separation unit has the first material layer with a refractive index of 0.6 times or more and 1.4 times or less of a refractive index of the semiconductor substrate.

(5)

The light detection device according to any one of (1) to (3), wherein the first material layer has at least one of a titanium oxide layer and an iron oxide layer.

(6)

The light detection device according to (4) or (5), wherein
the first material layer is provided to extend from one of the first surface and the second surface to at least a halfway position in a thickness direction of the semiconductor substrate.
   (7)

The light detection device according to any one of (4) to (6), wherein the inter-pixel separation unit has a second insulating film provided between the first material layer and the semiconductor substrate.

(8)

The light detection device according to any one of (1) to (7), wherein the connection unit is integrally formed with the intra-pixel separation unit.

(9)

The light detection device according to any one of (1) to (8), wherein
the intra-pixel separation unit when viewed in a plane along a thickness direction of the semiconductor substrate has
a first linear portion that extends in a first direction,
a second linear portion that extends in a second direction intersecting with the first direction, and
an intersecting portion that is arranged in an intersecting region where the first linear portion and the second linear portion intersect with each other,
the first linear portion and the second linear portion are made of the same material, and
the intersecting portion is made of a material different from the material of the first linear portion and the second linear portion.
   (10)

The light detection device according to (9), wherein the intra-pixel separation unit has, as the first material layer,
a second material layer used in the first linear portion and the second linear portion and
a third material layer used in the intersecting portion, and
a difference in refractive index between the third material layer and the semiconductor substrate is greater than a difference in refractive index between the second material layer and the semiconductor substrate.
   (11)

The light detection device according to (10), wherein the third material layer has at least one of a titanium oxide layer and an iron oxide layer.

(12)

The light detection device according to (10) or (11), wherein the second material layer has a boron-doped amorphous silicon (BDAS) layer.

(13)

The light detection device according to any one of (1) to (12), including a lens layer provided on one of the first surface and the second surface, the lens layer having an on-chip lens arranged for each of the unit pixels.

(14)

The light detection device according to (13), including a color filter provided between the lens layer and the semiconductor substrate, the color filter configured to selectively transmit a color preset for each of the unit pixels.

(15)

The light detection device according to any one of (1) to (14), wherein each of the inter-pixel separation unit and the intra-pixel separation unit penetrates between the first surface and the second surface of the semiconductor substrate.

### REFERENCE SIGNS LIST

1, 1A, 1B, 1C, 1D, 1E Imaging device
10 Light receiving unit
11 Semiconductor substrate
11S1 First surface
11S2 Second surface
12, 12A, 12B, 12C, 12D Photoelectric conversion unit
13 Inter-pixel separation unit
14 Intra-pixel separation unit
14CR Intersecting portion
14L1 First linear portion
14L2 Second linear portion
15 Connection unit
16 Fixed charge layer
20 Focusing unit
21 Color filter
21B Color filter (that selectively transmits blue light)
21G Color filter (that selectively transmits green light)
21R Color filter (that selectively transmits red light)
22 Light shielding unit
23 Flattening layer
24 On-chip lens
24L Lens layer
30 Multilayer wiring layer
31, 32, 33 Wiring layer
34 Interlayer insulating layer
100A Pixel unit
111 Vertical driving circuit
112 Column signal processing circuit
113 Horizontal driving circuit
114 Output circuit
115 Control circuit
116 Input/output terminal
121 Horizontal signal line
131 Gap
135, 145, 167 Insulating film
141 First material layer
142 Second material layer
143 Third material layer
161, 163, 164, 165 Material film
1000 Electronic equipment
1001 Lens group
1002 DSP circuit
1003 Frame memory
1004 Display unit
1005 Recording unit
1006 Operation unit
1007 Power supply unit
1008 Bus line
11000 Endoscopic surgery system
11100 Endoscope
11101 Lens barrel
11102 Camera head
11110 Surgical instrument
11111 Pneumoperitoneum tube
11112 Energy treatment tool
11120 Support arm device
11131 Surgeon (doctor)
11132 Patient
11153 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402 Imaging unit
11403 Driving unit
11404 Communication unit
11405 Camera head control unit
11411 Communication unit
11412 Image processing unit
11413 Control unit
12000 Vehicle control system
12001 Communication network
12010 Drive system control unit
12020 Body system control unit
12030 External information detection unit
12031 Imaging unit
12040 Internal information detection unit
12041 Driver's state detection unit
12050 Integrated control unit
12051 Microcomputer
12052 Audio/image output unit
12061 Audio speaker
12062 Display unit
12063 Instrument panel
12100 Vehicle
12101, 12102, 12103, 12104, 12105 Imaging unit
12111, 12112, 12113, 12114 Imaging range
H1, H2, H3 Slit
I In-vehicle network
IC External control
Lread Pixel driving line
Lsig Vertical signal line
M1, M2, M3 Mask
P Unit pixel
Ra, Rb, Rc, Rd Region
RST Reset transistor
RSTsig Driving signal
S1 Light incidence side
SEL Selection transistor
SELsig Driving signal
TR1, TR2, TR3, TR4 Transfer transistor
TRsig Driving signal

1. A computer-implemented method, at least a portion of which is performed by a computing device comprising at least one processor, the method comprising:
partitioning, by the computing device and in a containerized environment, a backup data storage into a first logical partition and a second logical partition, the partitioning of the backup data storage into the second logical partition including configuring a virtual air gap in the backup data storage as a protected space;
detecting, by the computing device, at least one root process running in the containerized environment that initiates one or more operations on the backup data storage;
determining, by the computing device, whether the at least one root process is a trusted root process or a non-trusted root process based at least on whether the at least one root process corresponds to a binary inside the containerized environment and whether the at least one root process is a top-level process; and
performing, by the computing device and upon determining that the at least one root process is the non-trusted root process, a security action that protects against unauthorized access to the backup data storage.

2. The computer-implemented method of claim 1, further comprising permitting modification access to the backup data storage for the trusted root process.

3. The computer-implemented method of claim 1, wherein the first logical partition comprises an unprotected space.

4. The computer-implemented method of claim 3, wherein configuring the virtual air gap in the backup data storage as the protected space comprises:
enabling read-only access on the backup data storage for the non-trusted root process; and
enabling modification access for the trusted root process.

5. The computer-implemented method of claim 1, wherein detecting the at least one root process for executing the one or more operations on the backup data storage comprises detecting a root user process for performing at least one of a file data and a metadata backup operation on the backup data storage.

6. The computer-implemented method of claim 5, wherein the at least one of the file data and the metadata backup operation comprises:
a read operation;
a write operation;
an open operation;
a delete operation; or
a rename binaries operation.

7. The computer-implemented method of claim 1, wherein determining whether the at least one root process is the trusted root process or the non-trusted root process comprises:
identifying each of a group of target processes associated with a trusted path list as the trusted root process; and
identifying any process absent from the group of the target processes associated with the trusted path list as the non-trusted root process.

8. The computer-implemented method of claim 1, wherein the trusted root process comprises at least one of:
application product binaries in the containerized environment installed at paths listed in a trusted path list that includes a well-known path;
operating system shared libraries;
pre-defined scripts associated with the application product binaries installed at the paths listed in the trusted path list; and
pre-defined utilities associated with the application product binaries installed at the paths listed in the trusted path list.

9. The computer-implemented method of claim 1, wherein performing the security action that protects against the unauthorized access to the backup data storage includes preventing modification access for the non-trusted root process comprises by failing a file modification operation by the non-trusted root process.

10. The computer-implemented method of claim 1, wherein performing the security action that protects against the unauthorized access to the backup data storage including preventing modification access for the non-trusted root process comprises by failing a metadata modification operation by the non-trusted root process.

11. A system for protecting persistent storage in a containerized environment, the system comprising:
at least one physical processor; and
physical memory comprising computer-executable instructions and one or more modules that, when executed by the physical processor, cause the physical processor to:
partition, by a partition module, a backup data storage into a first logical partition and a second logical partition in the containerized environment, the partitioning of the backup data storage into the second logical partition including configuring a virtual air gap in the backup data storage as a protected space;
detect, by a detection module, at least one root process running in the containerized environment that initiates one or more operations on the backup data storage;
determine, by a determining module, whether the at least one root process is a trusted root process or a non-trusted root process based at least on whether the at least one root process corresponds to a binary inside the containerized environment and whether the at least one root process is a top-level process; and
perform, by a security module, a security action that protects against unauthorized access to the backup data storage.

12. The system of claim 11, wherein the security module further performs the security action by permitting modification access to the backup data storage for the trusted root process.

13. The system of claim 11, wherein the first logical partition comprises an unprotected space.

14. The system of claim 13, wherein the partition module configures the virtual air gap in the backup data storage as the protected space by:
enabling read-only access on the backup data storage for the non-trusted root process; and
enabling modification access for the trusted root process.

15. The system of claim 11, wherein the detection module detects the at least one root process for executing the one or more operations on the backup data storage by detecting a root user process for performing at least one of a file data and a metadata backup operation on the backup data storage.

16. The system of claim 15, wherein the at least one of the file data and the metadata backup operation comprises:
a read operation;
a write operation;
an open operation;
a delete operation; or
a rename binaries operation.

17. The system of claim 11, wherein the determining module determines whether the at least one root process is the trusted process or the non-trusted root process by:
identifying each of a group of target processes associated with a trusted path list as the trusted root process; and
identifying any process absent from the group of the target processes associated with the trusted path list as the non-trusted root process.

18. The system of claim 11, wherein the trusted root process comprises at least one of:
application product binaries in the containerized environment installed at paths listed in a trusted path list that includes a well-known path;
operating system shared libraries;
pre-defined scripts associated with the application product binaries installed at the paths listed in the trusted path list; and
pre-defined utilities associated with the application product binaries installed at the paths listed in the trusted path list.

19. The system of claim 11, wherein the security module performs the security action that protects against the unauthorized access to the backup data storage by preventing modification access for the non-trusted root process, the preventing including failing a file modification operation by the non-trusted root process.

20. A non-transitory computer-readable medium comprising one or more computer-executable instructions that, when executed by at least one processor of a computing device, cause the computing device to:
partition a backup data storage into a first logical partition and a second logical partition, the partitioning of the backup data storage into the second logical partition including configuring a virtual air gap in the backup data storage as a protected space;
detect at least one root process running in a containerized environment that initiates one or more operations on the backup data storage;
determine whether the at least one root process is a trusted root process or a non-trusted root process based at least on whether the at least one root process corresponds to a binary inside the containerized environment and whether the at least one root process is a top-level process; and
perform a security action that protects against unauthorized access to the backup data storage.
